(19) United States
(12) Patent Application Publication
(10) Pub. No.: US 2025/0293704 A1
(43) Pub. Date: Sep. 18, 2025

(54) Bandwidth Compressed Data Movement and Footprint Compression

(71) Applicant: QUALCOMM Incorporated, San Diego, CA (US)

(72) Inventors: Andrew Edmund TURNER, San Diego, CA (US); Jeffrey SHABEL, San Diego, CA (US)

(21) Appl. No.: 18/604,738

(22) Filed: Mar. 14, 2024

(51) Int. Cl. H03M 7/30

(52) U.S. Cl. CPC H03M 7/3062; H03M 7/3084

(57) ABSTRACT

Various embodiments include a bandwidth compressed data mover system and methods for implementing functions of the bandwidth compressed data mover system for moving bandwidth compressed data. Embodiments may include identifying valid bandwidth compressed data of bandwidth compressed data stored in a memory based on a configuration of a bandwidth compression technique used to generate the bandwidth compressed data, in which the bandwidth compressed data includes valid bandwidth compressed data and invalid bandwidth compressed data, loading the valid bandwidth compressed data from the memory, and writing the valid bandwidth compressed data to an output device. Embodiments may include copying the valid bandwidth compressed data loaded from the memory to the output device. Embodiments may include serializing the valid bandwidth compressed data loaded from the memory to produce serialized valid bandwidth compressed data and writing the serialized valid bandwidth compressed data to the output device.

### BACKGROUND

Bandwidth compression is a vital component of many computer systems. Bandwidth compression leaves invalid data in portions of memory such that accesses to bandwidth compressed data requires less bandwidth than data that is not bandwidth compressed, and that bandwidth compressed data remains in the same expected location as data that is not bandwidth compressed. Bandwidth compressed data that is moved (e.g., between memories or chips) or footprint compressed includes the invalid data in the move and the compression. Moving and compressing the bandwidth compressed data including the invalid data incurs costs. For example, for bandwidth compression of 3:1, bandwidth compressed data moves and compression work is performed on 200% more data than required. Additionally, the invalid data may significantly reduce compression efficiency. As data is increasingly targeted for bulk data compression for ZRAM, suspend, and other use cases, the ability to handle bandwidth compressed data becomes increasingly important.

### SUMMARY

Various aspects provide methods and apparatuses for implementing such methods for implementing a bandwidth compressed data mover system of a computing device for moving bandwidth compressed data. Various aspects may include identifying valid bandwidth compressed data of bandwidth compressed data stored in a memory based on a configuration of a bandwidth compression technique used to generate the bandwidth compressed data, wherein the bandwidth compressed data includes valid bandwidth compressed data and invalid bandwidth compressed data, loading the valid bandwidth compressed data from the memory, and writing the valid bandwidth compressed data to an output device. In some aspects, writing the valid bandwidth compressed data to the output device may include copying the valid bandwidth compressed data loaded from the memory to the output device.

Some aspects may further include serializing the valid bandwidth compressed data loaded from the memory to produce serialized valid bandwidth compressed data, wherein writing the valid bandwidth compressed data to the output device may include writing the serialized valid bandwidth compressed data to the output device.

Some aspects may further include compressing the serialized valid bandwidth compressed data to produce compressed serialized valid bandwidth compressed data, wherein writing the serialized valid bandwidth compressed data to the output device may include writing the compressed serialized valid bandwidth compressed data to the output device.

In some aspects, writing the serialized valid bandwidth compressed data to the output device may include transmitting the serialized valid bandwidth compressed data to a decoder, decoding the serialized valid bandwidth compressed data in the decoder to produce the valid bandwidth compressed data, and writing the valid bandwidth compressed data decoded to the output device.

In some aspects, identifying the valid bandwidth compressed data of the bandwidth compressed data stored in the memory based on the configuration of the bandwidth compression technique used to generate the bandwidth compressed data may include identifying an address in the memory for the valid bandwidth compressed data and a length of the valid bandwidth compressed data from metadata associated with the bandwidth compressed data, and loading the valid bandwidth compressed data from the memory may include loading the valid bandwidth compressed data from the memory based on the address in the memory for the valid bandwidth compressed data and the length of the valid bandwidth compressed data.

Some aspects may further include identifying an address in the memory for the valid bandwidth compressed data using a memory address speculation technique, calculating a length of the valid bandwidth compressed data, and generating metadata to associate with the valid bandwidth compressed data that identifies the address in the memory for the valid bandwidth compressed data and the length of the valid bandwidth compressed data. In some aspects, identifying the valid bandwidth compressed data of the bandwidth compressed data stored in the memory based on the configuration of the bandwidth compression technique used to generate the bandwidth compressed data may include identifying the address in the memory for the valid bandwidth compressed data and the length of the valid bandwidth compressed data from the metadata associated with the valid bandwidth compressed data, and loading the valid bandwidth compressed data from the memory may include loading the valid bandwidth compressed data from the memory based on the address in the memory for the valid bandwidth compressed data and the length of the valid bandwidth compressed data.

Some aspects may further include identifying mis-speculated valid bandwidth compressed data associated with the address in the memory for the valid bandwidth compressed data, storing the mis-speculated valid bandwidth compressed data in a speculation memory, identifying valid bandwidth compressed data from the mis-speculated valid bandwidth compressed data stored in the speculation memory for a request for bandwidth compressed data, and loading the valid bandwidth compressed data from the speculation memory. Some aspects may further include writing metadata associated with the valid bandwidth compressed data to the output device.

Further aspects include a computing device including a memory and a processor configured to perform operations of any of the methods summarized above. Further aspects include a non-transitory processor system-readable storage medium having stored thereon processor system-executable software instructions configured to cause a processor to perform operations of any of the methods summarized above. Further aspects include a computing device having means for accomplishing functions of any of the methods summarized above.

### BRIEF DESCRIPTION OF THE DRAWINGS

The accompanying drawings, which are incorporated herein and constitute part of this specification, illustrate example embodiments of various embodiments, and together with the general description given above and the detailed description given below, serve to explain the features of the claims.

FIG. 1 is a component block diagram illustrating an example computing device suitable for implementing various embodiments.

FIG. 2 is a component block diagram illustrating an example bandwidth compressed data mover of the computing device suitable for implementing various embodiments.

FIG. 3 is a component block diagram illustrating an example processing system of the computing device configured for implementing a bandwidth compressed data mover suitable for implementing various embodiments.

FIGS. 4-8 are component block and flow diagrams illustrating examples of bandwidth compressed data movement in the computing device suitable for implementing various embodiments.

FIG. 9 is a process flow diagram illustrating an example method for implementing bandwidth compressed data movement according to an embodiment.

FIG. 10 is a process flow diagram illustrating an example method for implementing bandwidth compressed data movement for bandwidth compressed data having associated metadata according to an embodiment.

FIGS. 11A and 11B are process flow diagrams illustrating an example method for implementing bandwidth compressed data movement for bandwidth compressed data without associated metadata according to an embodiment.

FIG. 12 is a component block diagram illustrating an example mobile computing device suitable for implementing various embodiments.

FIG. 13 is a component block diagram illustrating an example mobile computing device suitable for implementing various embodiments.

FIG. 14 is a component block diagram illustrating an example server suitable for implementing various embodiments.

### DETAILED DESCRIPTION

Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Various embodiments include methods, and computing devices implementing such methods of implementing bandwidth compressed data moving and footprint compression. Embodiments may include a bandwidth compressed data mover configured to load valid bandwidth compressed data from memory. The bandwidth compressed data may include valid bandwidth compressed data and invalid bandwidth compressed data in the memory. Load valid bandwidth compressed data from memory may exclude loading the invalid bandwidth compressed data. In some embodiments the bandwidth compressed data mover may be configured to load the valid bandwidth compressed data based on a configuration of a bandwidth compression technique used to generate the bandwidth compressed data and on metadata associated with the bandwidth compressed data. In some embodiments the bandwidth compressed data mover may be configured to generate metadata and associate the metadata with the valid bandwidth compressed data based on the configuration of the bandwidth compression technique used to generate the bandwidth compressed data.

In some embodiments the bandwidth compressed data mover may be configured to write the valid bandwidth compressed data to an output device. In some embodiments the bandwidth compressed data mover may be configured to write the valid bandwidth compressed data to the output device by copying the valid bandwidth compressed data to the output device. In some embodiments the bandwidth compressed data mover may be configured to serialize the valid bandwidth compressed data and write the serialized valid bandwidth compressed data to the output device. In some embodiments the bandwidth compressed data mover may be configured to compress the serialized valid bandwidth compressed data.

The term “computing device” is used herein to refer to stationary computing devices including personal computers, desktop computers, all-in-one computers, workstations, super computers, mainframe computers, embedded computers (such as in vehicles and other larger systems), computing systems within or configured for use in vehicles, servers, multimedia computers, and game consoles. The terms “computing device” and “mobile computing device” are used interchangeably herein to refer to any one or all of cellular telephones, smartphones, personal or mobile multi-media players, personal data assistants (PDA's), laptop computers, tablet computers, convertible laptops/tablets (2-in-1 computers), smartbooks, ultrabooks, netbooks, palm-top computers, wireless electronic mail receivers, multimedia Internet enabled cellular telephones, mobile gaming consoles, wireless gaming controllers, and computing systems embedded in vehicles that include a memory, and a programmable processor.

Various embodiments are described in terms of code, e.g., processing system-executable instructions, for ease and clarity of explanation, but may be similarly applicable to any data, e.g., code, program data, or other information stored in memory. The terms “code,” “data,” and “information” are used interchangeably herein and are not intended to limit the scope of the claims and descriptions to the types of code, data, or information used as examples in describing various embodiments.

Bandwidth compression is a vital component of many computer systems, current methods of working with bandwidth compressed data are imperfect. Bandwidth compression leaves invalid data in portions of memory. Consequently, moving bandwidth compressed data (e.g., between memories or chips), or compressing the footprint of bandwidth compressed data includes the invalid data in the move and the compression. Because of the including the invalid data moving and compressing bandwidth compressed data incurs costs beyond that required just for valid data. For example, for bandwidth compression of 3:1, moving bandwidth compressed data involves moving 200% more data than would be required if only valid data could be moved. Additionally, the invalid data may significantly reduce compression efficiency. As data is increasingly targeted for bulk data compression for ZRAM, suspend, and other use cases, accessing, moving, and using bandwidth compressed data efficiently becomes increasingly important.

Various embodiments overcome the foregoing problems by moving or compressing only the valid bandwidth compressed data, rather than moving or compressing bandwidth compressed data that includes the invalid bandwidth compressed data. Moving or compressing valid bandwidth compressed data may avoid the costs of moving or compressing the invalid bandwidth compressed data.

Some embodiments may include a bandwidth compressed data mover configured to move the valid bandwidth compressed data. Some embodiments may include the bandwidth compressed data mover moving the valid bandwidth compressed data by copying the valid bandwidth compressed data to an output device. Copying the valid bandwidth compressed data may reduce the amount of bandwidth compressed data moved as compared to moving the bandwidth compressed data along with the invalid bandwidth compressed data. Copying the valid bandwidth compressed data may use the same number of transactions to move the valid bandwidth compressed data while each transaction may transmit data compared to the amount of data transmitted when moving the bandwidth compressed data along with the invalid bandwidth compressed data. The number of transactions may remain the same and the amount of bandwidth compressed data may be less as the organization of the bandwidth compressed data may include the valid bandwidth compressed data as expected and replacement values for the invalid bandwidth compressed data. Moving or compressing replacement values may have lower cost than the cost of moving or compressing the actual invalid bandwidth compressed data. For example, the replacement values may be set such that moving or compressing the replacement values requires fewer voltage changes. Replacement values may include constant values, such as all “0” or all “1,” or certain patterns of values.

In some embodiments, the bandwidth compressed data mover may move the valid bandwidth compressed data by serializing the valid bandwidth compressed data and writing serialized valid bandwidth compressed data to an output device. Writing the serialized valid bandwidth compressed data may reduce the number of transactions and amount of bandwidth compressed data moved as compared to moving the bandwidth compressed data including the invalid bandwidth compressed data. Serializing the valid bandwidth compressed data may arrange the valid bandwidth compressed data into a continuous stream, reducing, even eliminating, unused spaces in the bandwidth compressed data where the invalid bandwidth compressed data would otherwise be located. The serialized valid bandwidth compressed data may be smaller in size as compared to bandwidth compressed data including the invalid bandwidth compressed data or valid bandwidth compressed data that is not serialized.

Writing the serialized valid bandwidth compressed data may transmit the contiguous stream of valid bandwidth compressed data, which may involve fewer transactions compared to writing bandwidth compressed data that includes the invalid bandwidth compressed data or valid bandwidth compressed data that is not serialized. The number of transactions may be reduced due to the reduction in space of the serialized valid bandwidth compressed data where the invalid bandwidth compressed data would otherwise be located. Some embodiments may further reduce the number of transactions and amount of bandwidth compressed data moved by compressing the serialized valid bandwidth compressed data and transmitting compressed serialized valid bandwidth compressed data.

The bandwidth compressed data mover may identify the valid bandwidth compressed data from the bandwidth compressed data in a memory. The bandwidth compressed data mover may identify the valid bandwidth compressed data based on a configuration of a bandwidth compression technique used to generate the bandwidth compressed data and on metadata associated with the bandwidth compressed data. In some embodiments, the metadata may be stored in memory and associated with the bandwidth compressed data stored in the memory. The bandwidth compressed data mover may use knowledge of how data is bandwidth compressed and locations and lengths of the bandwidth compressed data indicated in associated metadata to identify portions of the memory having the valid bandwidth compressed data.

In some embodiments, the bandwidth compressed data may be stored in the memory without associated metadata. The bandwidth compressed data mover may generate the metadata and associate the metadata with the valid bandwidth compressed data based on the configuration of the bandwidth compression technique used to generate the bandwidth compressed data. The bandwidth compressed data mover may use knowledge of how data is bandwidth compressed to identify portions of the memory storing the valid bandwidth compressed data. The bandwidth compressed data mover may generate metadata indicating locations and lengths of the valid bandwidth compressed data in the identified portions of the memory. The bandwidth compressed data mover may associate the generated metadata with the corresponding valid bandwidth compressed data.

The bandwidth compressed data mover may retrieve valid bandwidth compressed data from the memory based on the metadata associated with the bandwidth compressed data or the valid bandwidth compressed data. The metadata associated with the retrieved valid bandwidth compressed data may be packed with the valid bandwidth compressed data by the bandwidth compressed data mover. Based on a configuration of whether to copy or serialize the valid bandwidth compressed data, and/or to compress the serialized valid bandwidth compressed data, the bandwidth compressed data mover may write the valid bandwidth compressed data to the output device. For example, the bandwidth compressed data mover may copy the valid bandwidth compressed data to the output device. As another example, the bandwidth compressed data mover may serialize the valid bandwidth compressed data and write the serialized valid bandwidth compressed data to the output device. As another example, the bandwidth compressed data mover may compress the serialized valid bandwidth compressed data and write the compressed serialized valid bandwidth compressed data to the output device.

In various embodiments, the output device may be a different memory from the memory in which the bandwidth compressed data is stored, a same memory as the memory in which the bandwidth compressed data is stored, a processing system, a storage memory (or storage device), etc. The valid bandwidth compressed data may be copied to any output device different from the memory in which the bandwidth compressed data is stored. The valid bandwidth compressed data that is serialized and/or compressed may be written to any output device. The output device receiving the valid bandwidth compressed data that is serialized and/or compressed may also include a bandwidth compressed data mover that may decode the serialization (or deserialize) and/or compression (or decompress) of the valid bandwidth compressed data. Deserialization and/or decompression may be implemented prior to the bandwidth compressed data mover of the output device writing the valid bandwidth compressed data to the output device.

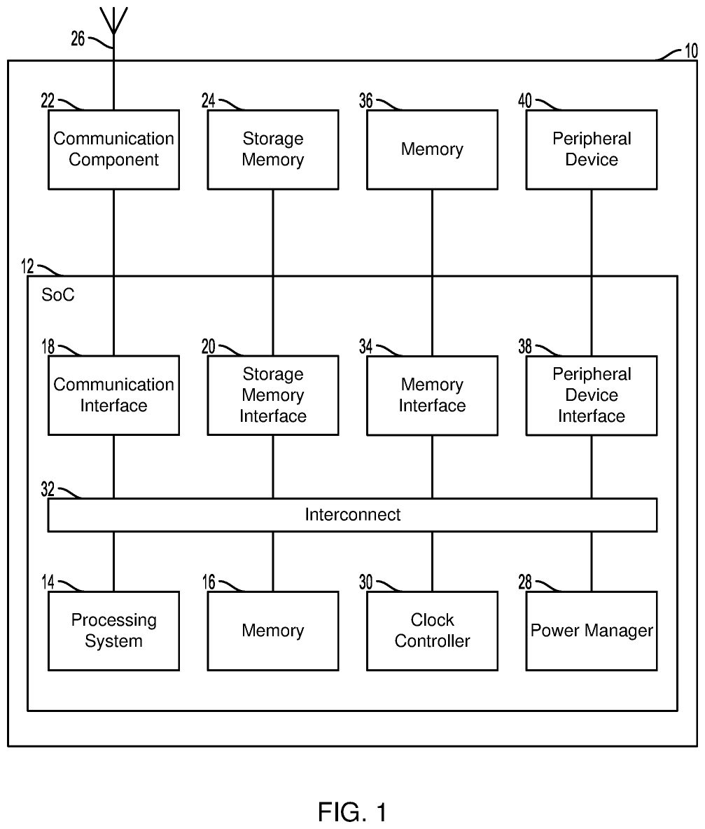

FIG. 1 illustrates a system including a computing device 10 suitable for use with various embodiments. With reference to FIG. 1, the computing device 10 may include a system-on-chip (SoC) 12 with a processing system 14, a memory 16, a communication interface 18, a storage memory interface 20, a memory interface 34, a power manager 28, a clock controller 30, a peripheral device interface 38, and an interconnect 32. The computing device 10 may further include a communication component 22, such as a wired or wireless modem, a storage memory 24, an antenna 26 for establishing a wireless communication link, a memory 36, and a peripheral device 40. The processing system 14 may include any of a variety of processing devices, for example a number of processor cores.

The term “system-on-chip” (SoC) is used herein to refer to a set of interconnected electronic circuits typically, but not exclusively, including a processing device, a memory, and a communication interface. A processing system 14 may include a variety of different types of processors and processor cores, such as a general purpose processor, a central processing unit (CPU), a digital signal processor (DSP), a graphics processing unit (GPU), an accelerated processing unit (APU), a secure processing unit (SPU), an artificial intelligence processing unit (AIPU), a subsystem processor of specific components of the computing device, such as an image processor for a camera subsystem or a display processor for a display, an auxiliary processor, a single-core processor, a multicore processor, a controller, and a microcontroller. A processing system 14 may further embody other hardware and hardware combinations, such as a field programmable gate array (FPGA), an application-specific integrated circuit (ASIC), other programmable logic device, discrete gate logic, transistor logic, performance monitoring hardware, watchdog hardware, and time references. Integrated circuits may be configured such that the components of the integrated circuit reside on a single piece of semiconductor material, such as silicon.

An SoC 12 may include one or more processing systems 14. The computing device 10 may include more than one SoC 12, thereby increasing the number of processing systems 14, processors, and processor cores. The computing device 10 may also include processing systems 14 that are not associated with an SoC 12. The processing systems 14 may each be configured for specific purposes that may be the same as or different from other processing systems 14 of the computing device 10. One or more of the processing systems 14, processors, or processor cores, of the same or different configurations may be grouped together. A group of processing systems 14, processors, or processor cores may be referred to as a multi-processor cluster.

The memory 16, 36 for the SoC 12 may be a volatile or non-volatile memory configured for storing data and processing system-executable code for access by the processing system 14. The computing device 10 and/or SoC 12 may include one or more memories 16, 36 configured for various purposes. One or more memories 16, 36 may include volatile memories such as random access memory (RAM) or main memory or cache memory. For example, the memories 16, 36 may include any of static RAM (SRAM), dynamic RAM (DRAM), etc. These memories 16, 36 may be configured to temporarily hold a limited amount of data received from a data sensor or subsystem, data and/or processing system-executable code instructions that are requested from a non-volatile memory 16, 24, loaded to the memories 16, 36 from the non-volatile memory 16, 24 in anticipation of future access based on a variety of factors, and/or intermediary processing data and/or processing system-executable code instructions produced by the processing system 14 and temporarily stored for future quick access without being stored in non-volatile memory 16, 24. The memory 16, 36 may include multiple physical memory components, such as memory chips, that may be logically combined and/or separated to form the memory 16, 36. The memory interface 34 and the memory 36 may work in unison to allow the computing device 10 to load and retrieve data and processing system-executable code on the memory 36.

The storage memory interface 20 and the storage memory 24 may work in unison to allow the computing device 10 to store data and processing system-executable code on a non-volatile storage medium. The storage memory 24 may be configured much like an embodiment of the memory 16 in which the storage memory 24 may store the data or processing system-executable code for access by one or more of the processing systems 14. The storage memory 24, being non-volatile, may retain the information after the power of the computing device 10 has been shut off. When the power is turned back on and the computing device 10 reboots, the information stored on the storage memory 24 may be available to the computing device 10. The storage memory 24 may include multiple physical memory components, such as storage memory drives, chips, discs, etc., that may be logically combined and/or separated to form the storage memory 24. The storage memory interface 20 may control access to the storage memory 24 and allow the processing system 14 to read data from and write data to the storage memory 24.

The power manager 28 may be configured to control power states of one or more power rails (not shown) for power delivery to the components of the SoC 12. In some embodiments, the power manager 28 may be configured to control amounts of power provided to the components of the SoC 12. For example, the power manager 28 may be configured to control connections between components of the SoC 12 and the power rails. As another example, the power manager 28 may be configured to control amounts of power on the power rails connected to the components of the SoC 12. The power manager 28 may be configured as a power management integrated circuit (power management ICs or PMIC).

A clock controller 30 may be configured to control clock signals transmitted to the components of the SoC 12. For example, the clock controller 30 may gate a component of the SoC 12 by disconnecting the component of the SoC 12 from a clock signal and may ungate the component of the SoC 12 by connecting the component of the SoC 12 to the clock signal.

A peripheral device interface 38 may enable components of the SoC 12, such as the processing system 14 and/or the memory 16, to communicate with a peripheral device 40. The peripheral device interface 38 may provide and manage physical and logical connections between the components of the SoC 12 and the peripheral device 40. The peripheral device interface 38 may also manage communication between the components of the SoC 12 and the peripheral device 40, such as by directing and/or allowing communications between transmitter and receiver pairs of the components of the SoC 12 and the peripheral device 40 for a communication. The communications may include transmission of memory access commands, addresses, data, interrupt signals, state signals, etc. A peripheral device 40 may be any component of the computing device 10 separate from the SoC 12, such as a processing system, a memory, a subsystem, etc. In some embodiments, the peripheral device interface 38 may include a PCIe root complex and may enable PCIe protocol communication between the components of the SoC 12 and the peripheral device 40. In some embodiments, the peripheral device 40 may be a component of the SoC 12.

The interconnect 32 may be a communication fabric, such as a communication bus, configured to communicatively connect the components of the SoC 12. The interconnect 32 may transmit signals between the components of the SoC 12. In some embodiments, the interconnect 32 may be configured to control signals between the components of the SoC 12 by controlling timing and/or transmission paths of the signals.

Some or all of the components, including components of the SoC 12, connected to the SoC 12, and the SoC 12, of the computing device 10 may be arranged differently, separated, and/or combined while still serving the functions of the various embodiments. The computing device 10 may not be limited to one of each of the components, and multiple instances of each component may be included in various configurations of the computing device.

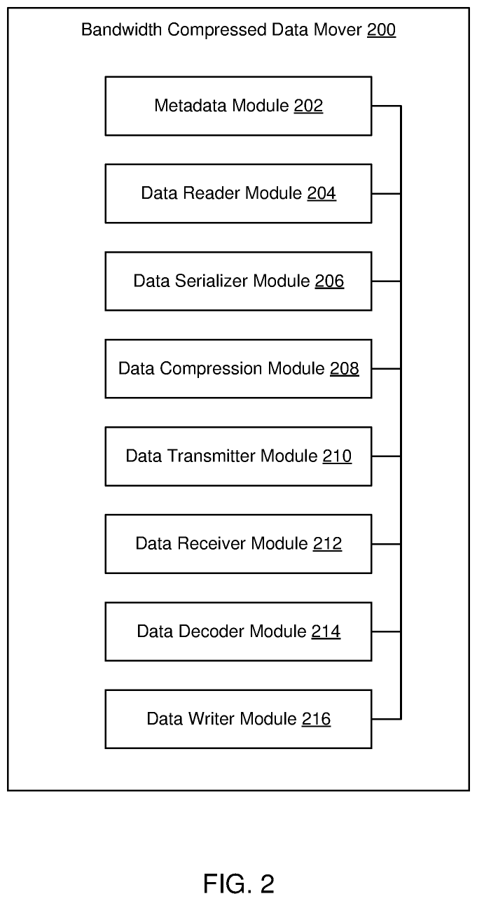

FIG. 2 illustrates an example bandwidth compression memory data mover 200 of a computing device (e.g., computing device 10 in FIG. 1) suitable for implementing various embodiments. With reference to FIGS. 1 and 2, the bandwidth compressed data mover 200 may be an integrated circuit having one or more modules 202-216 including interconnected semiconductor components configured to implement functions of the one or more modules 202-216. One or more bandwidth compressed data movers 200 may be integral components of the SoC (e.g., SoC 12 in FIG. 1) or other components (e.g., processing system 14, memory 16, communication interface 18, storage memory interface 20, memory interface 34, peripheral device interface 38, communication component 22, storage memory 24, memory 36, peripheral device 40 in FIG. 1) of the computing device.

A metadata module 202 of the bandwidth compressed data mover 200 may be configured to retrieve and read metadata that is stored in a memory (e.g., memory 16, 36 in FIG. 1). The metadata may be associated with bandwidth compressed data that is stored in the memory and may be configured to indicate a location and a length of the bandwidth compressed data in the memory. The metadata module 202 may retrieve and read the metadata associated with data targeted by a memory access request by a component of the computing device. For example, the component of the computing device may be a component for which the bandwidth compressed data mover 200 may be configured to implement bandwidth compressed data movement. The bandwidth compressed data mover 200 may be integral to component of the computing device.

Metadata may be identified for or calculated for valid bandwidth compressed data of the bandwidth compressed data in the memory. The metadata may be identified for or calculated for valid bandwidth compressed data based on the metadata associated with the bandwidth compressed data and a configuration of a bandwidth compression technique used to generate the bandwidth compressed data. The metadata module 202 may use the address and length of the bandwidth compressed data and knowledge of how data is converted to bandwidth compressed data to identify or calculate an address and length of the valid bandwidth compressed data. For example, knowledge of how data is converted to bandwidth compressed data may include the compression scheme, compression ratio, etc. that may be indicative of characteristics of the bandwidth compressed data resultant from the bandwidth compression technique.

The metadata module 202 may be configured to generate metadata and associate the metadata with bandwidth compressed data for which there is no associated metadata. The metadata may be generated for bandwidth compressed data that may be speculatively accessed for the memory access request by the component of the computing device. Speculative access of bandwidth compressed data may be based on one or more memory address speculation techniques, such as prediction, probing and checking, etc. The metadata module 202 may generate metadata associated with speculatively accessed bandwidth compressed data based on the speculative access and the configuration of the bandwidth compression technique used to generate the bandwidth compressed data. The metadata module 202 may use the address of the speculative access of the bandwidth compressed data and knowledge of how data is converted to bandwidth compressed data to generate an address and length of the bandwidth compressed data. The metadata may be associated with the speculatively accessed bandwidth compressed data.

Metadata may be generated and associated with the valid bandwidth compressed data of the speculatively accessed bandwidth compressed data. The metadata may be generated and associated with the valid bandwidth compressed data based on the speculative access and the configuration of the bandwidth compression technique used to generate the bandwidth compressed data. The address of the speculative access of the bandwidth compressed data and knowledge of how data is converted to bandwidth compressed data may be used to generate an address and length of the valid bandwidth compressed data. The metadata may be associated with the valid bandwidth compressed data of the speculatively accessed bandwidth compressed data.

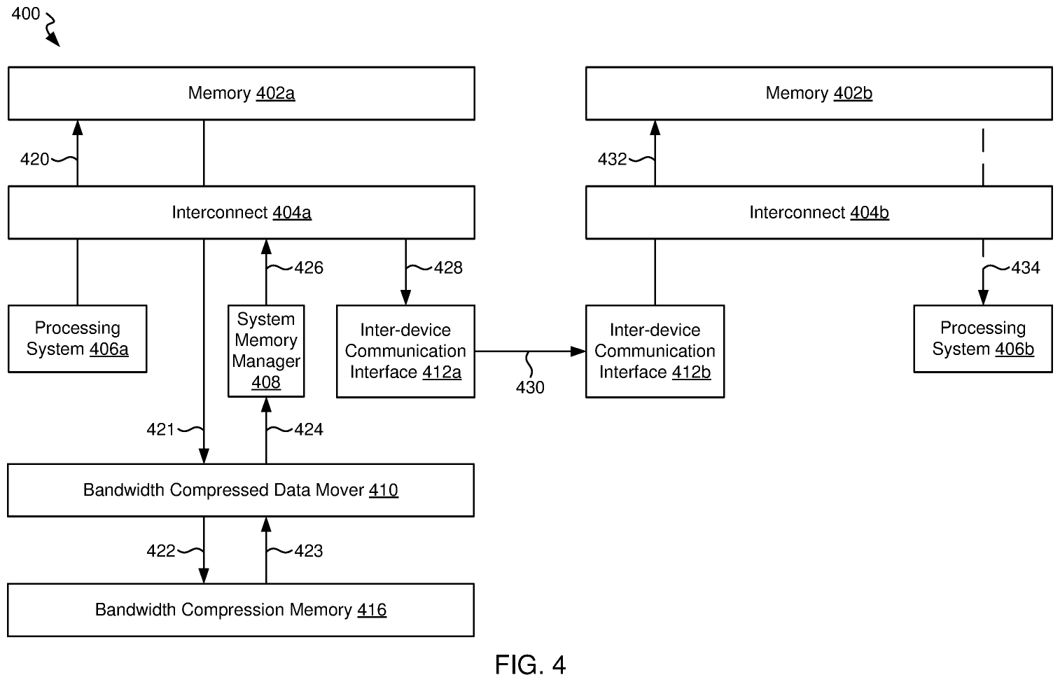

The speculatively accessed bandwidth compressed data or the valid bandwidth compressed data thereof that is not relevant to the memory access request may be referred to collectively or individually as mis-speculated bandwidth compressed data. The valid bandwidth compressed data of the speculatively accessed bandwidth compressed data that is not relevant to the memory access request may be referred to individually as mis-speculated valid bandwidth compressed data. The mis-speculated valid bandwidth compressed data and the associated metadata may be stored in a speculation memory (e.g., memory 16, 36, in FIG. 1) by the metadata module 202. The speculation memory may be memory located within or local to the bandwidth compressed data mover 200 (e.g., 416, 516 in FIGS. 4-8).

The metadata module 202 may be configured to retrieve and read the metadata or generate and associate the metadata one or more times per execution of the metadata module 202. Each time the metadata module 202 retrieves and reads the metadata or generates and associates the metadata may be for a different bandwidth compressed data. The number of times the metadata module 202 retrieves and reads the metadata or generates and associates the metadata may be based on a predetermined or dynamic efficiency granularity. For example, the efficiency granularity may be based on a multiple of the memory access length of the memory at which the bandwidth compressed data is stored.

A data reader module 204 of the bandwidth compressed data mover 200 may be configured to retrieve valid bandwidth compressed data from the memory or the speculation memory based on the metadata associated with the valid bandwidth compressed data. The metadata associated with the valid bandwidth compressed data may include characteristics of the valid bandwidth compressed data retrieved from the metadata or derived from the metadata and passed to the data reader module 204 by the metadata module 202. The characteristics of the valid bandwidth compressed data may include the address and length of the valid bandwidth compressed data in the memory or the speculation memory. The data reader module 204 may retrieve the valid bandwidth compressed data based on characteristics of the valid bandwidth compressed data received from the metadata module 202. For metadataless operations, the data reader module 204 may retrieve the data from the speculation memory, possibly valid bandwidth compressed mis-speculated data.

A data serializer module 206 of the bandwidth compressed data mover 200 may be configured to identify whether the bandwidth compressed data mover 200 is set for serializing the valid bandwidth compressed data retrieved by the data reader module 204. The bandwidth compressed data mover 200 may be set for copying or serializing the valid bandwidth compressed data. A setting for serializing the valid bandwidth compressed data may be part of the received memory access command, may be preset at a configuration memory, or may be dynamically set at the configuration memory.

In some embodiments, the memory access command may include a configuration signal having a value configured to indicate to the data serializer module 206 whether to serialize the valid bandwidth compressed data. In some embodiments, the configuration memory may include a register, an electronic fuse (or eFuse), a pin, etc. that may provide the configuration signal having the value configured to indicate to the data serializer module 206 whether to serialize the valid bandwidth compressed data. In some embodiments, the configuration memory may be preset with the configuration signal during manufacturing or programming, such as at a boot time, of the bandwidth compressed data mover 200. In some embodiments, the configuration memory may be dynamically set with the configuration signal at a runtime of the bandwidth compressed data mover 200.

In some embodiments, the value of the configuration signal configured to indicate to the data serializer module 206 whether to serialize the valid bandwidth compressed data may be use case specific. For example, the value of the configuration signal may be configured to indicate to serialize the valid bandwidth compressed data for writing the valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device having a bandwidth compressed data mover 200. As another example, the value of the configuration signal may be configured to indicate to serialize the valid bandwidth compressed data for writing the serialized valid bandwidth compressed data to a memory (e.g., memory 16, 36, storage memory 24 in FIG. 1), including the memory in which the valid bandwidth compressed data is stored. As another example, the value of the configuration signal may be configured to indicate not to serialize (or to copy) the valid bandwidth compressed data for writing the valid bandwidth compressed data to an output device not having bandwidth compressed data mover 200.

In response to the configuration signal having the value configured to indicate to the data serializer module 206 to serialize the valid bandwidth compressed data, the data serializer module 206 may serialize the valid bandwidth compressed data. The data serializer module 206 may serialize the valid bandwidth compressed data by formatting the valid bandwidth compressed data as a stream of data. For example, the data serializer module 206 may compact the valid bandwidth compressed data by rearranging the valid bandwidth compressed data. The valid bandwidth compressed data may be rearranged in a manner reducing, even eliminating, unused space between the valid bandwidth compressed data. The unused space between the valid bandwidth compressed data may be space created by not retrieving invalid bandwidth compressed data.

The data serializer module 206 may also generate metadata associated with the serialized valid bandwidth compressed data configured to enable decoding, by deserialization, of the serialized valid bandwidth compressed data. For example, the metadata associated with the serialized valid bandwidth compressed data may include sizes for the portions of the serialized valid bandwidth compressed data. The metadata associated with the serialized valid bandwidth compressed data may also include spacing between the portions of the serialized valid bandwidth compressed data.

A data compression module 208 of the bandwidth compressed data mover 200 may be configured to compress valid bandwidth compressed data serialized by the data serializer module 206. Compressing the serialized valid bandwidth compressed data may be optional and use case specific. For example, compressing the serialized valid bandwidth compressed data may be implemented based on a type of data of the serialized valid bandwidth compressed data. The type of data may be larger scale redundant information. As another example, compressing the serialized valid bandwidth compressed data may be implemented based on writing the valid bandwidth compressed data to an output device of the computing device having a bandwidth compressed data mover 200. As another example, compressing the serialized valid bandwidth compressed data may be implemented based on writing the compressed serialized valid bandwidth compressed data to a memory (e.g., memory 16, 36, storage memory 24 in FIG. 1), including the memory in which the valid bandwidth compressed data is stored.

The data compression module 208 may also generate metadata associated with the compressed serialized valid bandwidth compressed data configured to enable decoding, by decompression, of the compressed serialized valid bandwidth compressed data. For example, the metadata associated with the compressed serialized valid bandwidth compressed data may include details of the valid bandwidth compressed data compression, such as size of the compressed serialized valid bandwidth compressed data, compression algorithm identifier, compression parameters, etc.

A data transmitter module 210 of the bandwidth compressed data mover 200 may be configured to transmit the valid bandwidth compressed data, in any format, to an output device targeted by the memory access command. In some embodiments, the valid bandwidth compressed data transmitted may be the valid bandwidth compressed data retrieved by the data reader module 204. In some embodiments, the valid bandwidth compressed data transmitted may be the serialized valid bandwidth compressed data serialized by the data serializer module 206. In some embodiments, the valid bandwidth compressed data transmitted may be the compressed serialized valid bandwidth compressed data compressed by the data compression module 208. In some embodiments, the output device may be the same memory from which the valid bandwidth compressed data is retrieved by the data reader module 204.

Along with the valid bandwidth compressed data, the transmitter module 210 may transmit any metadata associated with the valid bandwidth compressed data. For example, the metadata may include metadata associated with the valid bandwidth compressed data and retrieved from the memory by the metadata module 202. As another example, the metadata may include metadata generated by the metadata module 202 for valid bandwidth compressed data not associated with metadata in the memory. As another example, the metadata may include metadata data generated for and associated with serialized valid bandwidth compressed data by the data serialized module 206. As another example, the metadata may include metadata data generated for and associated with compressed serialized valid bandwidth compressed data by the data compression module 208.

A data receiver module 212 of the bandwidth compressed data mover 200 may be configured to receive valid bandwidth compressed data. The valid bandwidth compressed data received may be valid bandwidth compressed data transmitted by a data transmitter module 210 of another bandwidth compressed data mover 200. The valid bandwidth compressed data may include, valid bandwidth compressed data, serialized valid bandwidth compressed data, or compressed serialized valid bandwidth compressed data. Along with the valid bandwidth compressed data, the data receiver module 212 may receive any metadata associated with the valid bandwidth compressed data. The metadata may include metadata associated with valid bandwidth compressed data, serialized valid bandwidth compressed data, or compressed serialized valid bandwidth compressed data.

A data decoder module 214 of the bandwidth compressed data mover 200 may be configured to decode the valid bandwidth compressed data received by the data receiver module 212. In some embodiments, the received valid bandwidth compressed data may be serialized valid bandwidth compressed data. The data decoder module 214 may decode, by deserializing, the compressed serialized valid bandwidth compressed data. In some embodiments, the received valid bandwidth compressed data may be compressed serialized valid bandwidth compressed data. The data decoder module 214 may decode, by decompressing or deserializing, the compressed serialized valid bandwidth compressed data.

The data decoder module 214 may use the metadata associated with valid bandwidth compressed data and received by the data receiver module 212 to decode the valid bandwidth compressed data. For example, metadata associated with compressed serialized valid bandwidth compressed data may include information regarding the compression process that may enable the data decoder module 214 to decompress the compressed serialized valid bandwidth compressed data. As another example, metadata associated with serialized valid bandwidth compressed data may include information regarding the organization of the serialized valid bandwidth compressed data that may enable the data decoder module 214 to reserialize the serialized valid bandwidth compressed data. The metadata associated with valid bandwidth compressed data may be used by the data decoder module 214 to configure the valid bandwidth compressed data for processing or storage, including by calculating addresses for the valid bandwidth compressed data. The data decoder module 214 may generate metadata associated with the valid bandwidth compressed data having the calculated address for the valid bandwidth compressed data.

Some or all of the functions of the data decoder module 214 may be optionally implemented. For example, the received valid bandwidth compressed data may be decoded for processing by the component of the computing device having the bandwidth compressed data mover 200. Decoding may include deserializing serialized valid bandwidth compressed data or decompressing and deserializing compressed serialized valid bandwidth compressed data. As another example, the received valid bandwidth compressed data may be at least partially decoded for storage by the component of the computing device having the bandwidth compressed data mover 200. Partial decoding may include decompressing without deserializing compressed serialized valid bandwidth compressed data. As another example, the received valid bandwidth compressed data may not be decoded and may be stored by the component of the computing device having the bandwidth compressed data mover 200.

A data writer module 216 of the bandwidth compressed data mover 200 may be configured to write the valid bandwidth compressed data received by the data receiver module 212 to the output device targeted by the memory access command. The output device may be the component of the computing device having the bandwidth compressed data mover 200. The valid bandwidth compressed data may be valid bandwidth compressed data that did not need decoding by the data decoder module 214. The valid bandwidth compressed data may be valid bandwidth compressed data at least partially decoding by the data decoder module 214. For copied valid bandwidth compressed data, the data writer module 216 may use addresses from the metadata received along with the valid bandwidth compressed data by the data receiver module 212 to write the valid bandwidth compressed data to the output device. For decoded valid bandwidth compressed data, the data writer module 216 may use addresses from the metadata received generated by the data decoder module 214 to write the valid bandwidth compressed data to the output device.

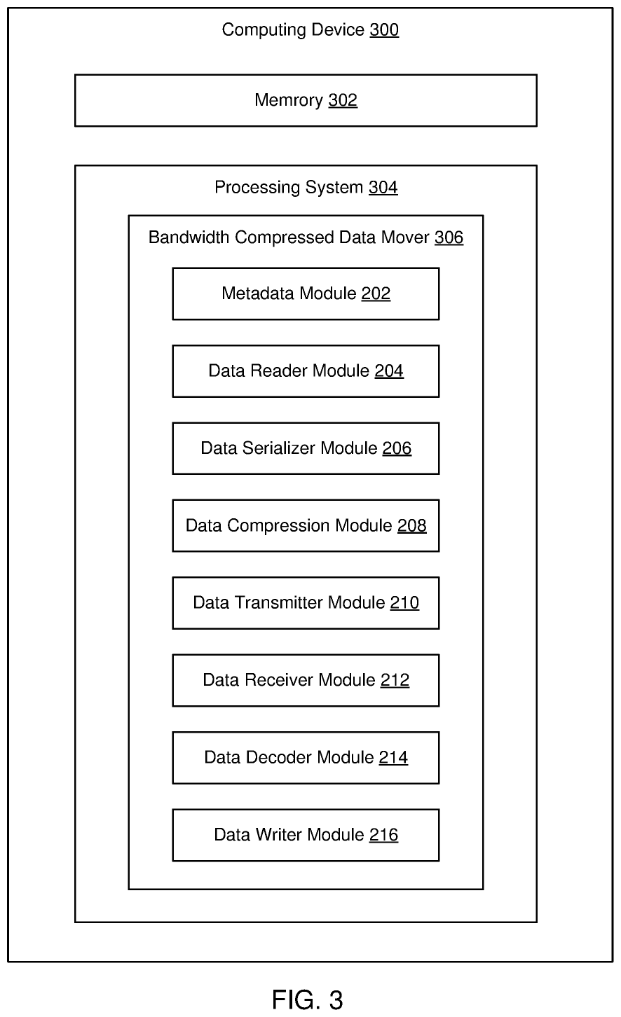

FIG. 3 illustrates an example processing system 304 (e.g., processing system 14 in FIG. 1) of a computing device 300 (e.g., computing device 10 in FIG. 1) configured for implementing a bandwidth compressed data mover 306 suitable for implementing various embodiments. With reference to FIGS. 1-3, the bandwidth compressed data mover 306 may be software having one or more modules 202-216 configured for implementing functions of the bandwidth compressed data mover 306. The processing system 304 be configured with processing system-executable instructions of the one or more modules 202-216 for implementing functions of the one or more modules 202-216. The processing system 304 may be an integral component of the SoC (e.g., SoC 12 in FIG. 1) or other components (e.g., processing system 14, memory 16, communication interface 18, storage memory interface 20, memory interface 34, peripheral device interface 38, communication component 22, storage memory 24, memory 36, peripheral device 40 in FIG. 1) of the computing device. The computing device may include a memory 302 (e.g., memory 16, 36, storage memory 24 in FIG. 1) that may be a non-transitory processing system-readable medium storing the processing system-executable instructions of the one or more modules 202-216 for implementing functions of the one or more modules 202-216. The one or more modules 202-216 may be implemented in similarly and include similar functions as described herein with reference to FIG. 2.

In some embodiments, a computing device (e.g., computing device 10, 300 in FIGS. 1 and 3) may include a combination of the bandwidth compressed data mover implemented in hardware (e.g., bandwidth compressed data mover 200 in FIG. 2) and implemented in software (e.g., bandwidth compressed data mover 306 in FIG. 3) by the processing system (e.g., processing system 14, 304 in FIGS. 1 and 3). Any combination of the modules 202-216 may be implemented by the bandwidth compressed data mover implemented in hardware and implemented in software. In other words, some of the modules 202-216 may be implemented by the bandwidth compressed data mover implemented in hardware and other of the modules 202-216 may be implemented by the bandwidth compressed data mover implemented in software. In some embodiments, the bandwidth compressed data mover implemented in hardware may be an integral component of the processing system implementing the bandwidth compressed data mover implemented in software.

FIGS. 4-8 illustrate examples of bandwidth compressed data movement in the computing device (e.g., computing device 10, 300 in FIGS. 1 and 3) suitable for implementing various embodiments. With reference to FIGS. 1-8, a bandwidth compressed data movement system 400, 500, 600, 700, 800 may include components of the computing device, including at least one memory 402a, 402b (e.g., memory 16, 36 in FIG. 1), at least one processing system 406a, 406b (e.g., processing system 14, 300 in FIGS. 1 and 3), and at least one system memory manager 408, 508 (e.g., memory interface 34 in FIG. 1), at least one bandwidth compressed data mover 410, 510 (e.g., bandwidth compressed data mover 200, 306 in FIGS. 2 and 3), and at least one bandwidth compression memory 416, 516 (e.g., memory 16, 36 in FIG. 1). The bandwidth compressed data movement system 400, 500, 600, 700, 800 may also include at least one interconnect 404a, 404b (e.g., interconnect 32 in FIG. 1) configured to connect associated components. For example, components may be integral to a chip package or a semiconductor substrate, and the components may be connected via the interconnect 404a, 404b of the chip package or the semiconductor substrate. The bandwidth compression memory 416 may be one or more memories configured to store metadata, bandwidth compressed data, including non-speculated data, properly speculated data, or mis-speculated data.

In each of the example bandwidth compressed data movement systems 400, 500, 600, 700, 800, the processing system 406a may implement a process 420 storing bandwidth compressed data to the memory 402a. In some embodiments, in response to a memory access request for the bandwidth compressed data stored in the memory 402a, the bandwidth compressed data mover 410 may implement a process 421 to retrieve the bandwidth compressed data from the memory 402a. The bandwidth compressed data mover 410 may implement the process 421 to retrieve metadata associated with the bandwidth compressed data from the memory 402a. In some embodiments, the bandwidth compressed data mover 410 may implement the process 421 to retrieve bandwidth compressed data from the memory 402a by implementing speculative access techniques. The speculative access techniques implemented in process 421 may involve testing the bandwidth compressed data retrieved from the memory 402a. The bandwidth compressed data from the memory 402a speculatively accessed by the bandwidth compressed data mover 410 may be unassociated with metadata. Based on the results of testing the bandwidth compressed data, some or all of the bandwidth compressed data retrieved from the memory 402a may be identified as properly speculated, having relevance to the memory access request, or as mis-speculated, not having relevance to the memory access request.

The bandwidth compressed data mover 410 may implement a process 422 for storing the bandwidth compressed data in the bandwidth compression memory 416. In some embodiments, the bandwidth compressed data may include properly speculated and mis-speculated data. For the bandwidth compressed data retrieved using speculative access techniques, as part of the process 421, the bandwidth compressed data mover 410 may generate metadata for and associate the metadata with the bandwidth compressed data. The bandwidth compressed data mover 410 may store the metadata in the bandwidth compression memory 416 in association with the stored bandwidth compressed data as part of the process 422. The metadata associated with the bandwidth compressed data may include information indicating a location of the bandwidth compressed data, a size of the bandwidth compressed data, etc. in the bandwidth compression memory 416.

The bandwidth compressed data mover 410 may implement a process 423 to retrieve valid bandwidth compressed data from the bandwidth compression memory 416. The bandwidth compressed data is associated with metadata stored in the bandwidth compression memory 416. The bandwidth compressed data mover 410 may implement the process 423 by retrieving the associated metadata and identifying the valid bandwidth compressed data based on the associated metadata and a configuration of a bandwidth configuration technique used to generate the bandwidth compressed data. In some embodiments, the bandwidth compressed data mover 410 may retrieve bandwidth compressed data generated in response to the memory access request. In some embodiments, the bandwidth compressed data mover 410 may retrieve bandwidth compressed data including properly speculated data or mis-speculated data that has become relevant to a subsequent memory access request.

In some embodiments, the bandwidth compressed data mover 410 may implement the process 423 further by serializing the valid bandwidth compressed data and generating metadata for and associating the metadata with the serialized valid bandwidth compressed data. In some embodiments, the bandwidth compressed data mover 410 may implement the process 423 further by compressing the serialized valid bandwidth compressed data and generating metadata for and associating the metadata with the compressed serialized valid bandwidth compressed data.

In the example illustrated in FIG. 4, the bandwidth compressed data movement systems 400 may be configured to copy valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device. For example, the output device may be the memory 402b or the processing system 406b. The bandwidth compressed data mover 410 may implement a process to write the valid bandwidth compressed data to the output device 402b, 406b.

The bandwidth compressed data mover 410 may implement a process 424 transmitting the valid bandwidth compressed data and associated metadata to the system memory manager 408. The system memory manager 408 may implement a process 426 transmitting the valid bandwidth compressed data and associated metadata to the interconnect 404a. The interconnect 404a may implement a process 428 transmitting the valid bandwidth compressed data and associated metadata to an inter-device communication interface 412a (e.g., peripheral device interface 38 in FIG. 1). In some embodiments, the bandwidth compressed data mover 410 may include a virtual address data buffer (not shown) mapped to the inter-device communication interface 412a to enable writing across the inter-device communication interface 412a. The inter-device communication interface 412a may implement a process 430 transmitting the valid bandwidth compressed data and associated metadata to the inter-device communication interface 412b.

The inter-device communication interface 412b may implement a process 432 transmitting the valid bandwidth compressed data and associated metadata to the memory 402b where the valid bandwidth compressed data and associated metadata may be stored. In some embodiments, the memory 402b may optionally implement a process 434 transmitting the valid bandwidth compressed data and associated metadata to the processing system 406b.

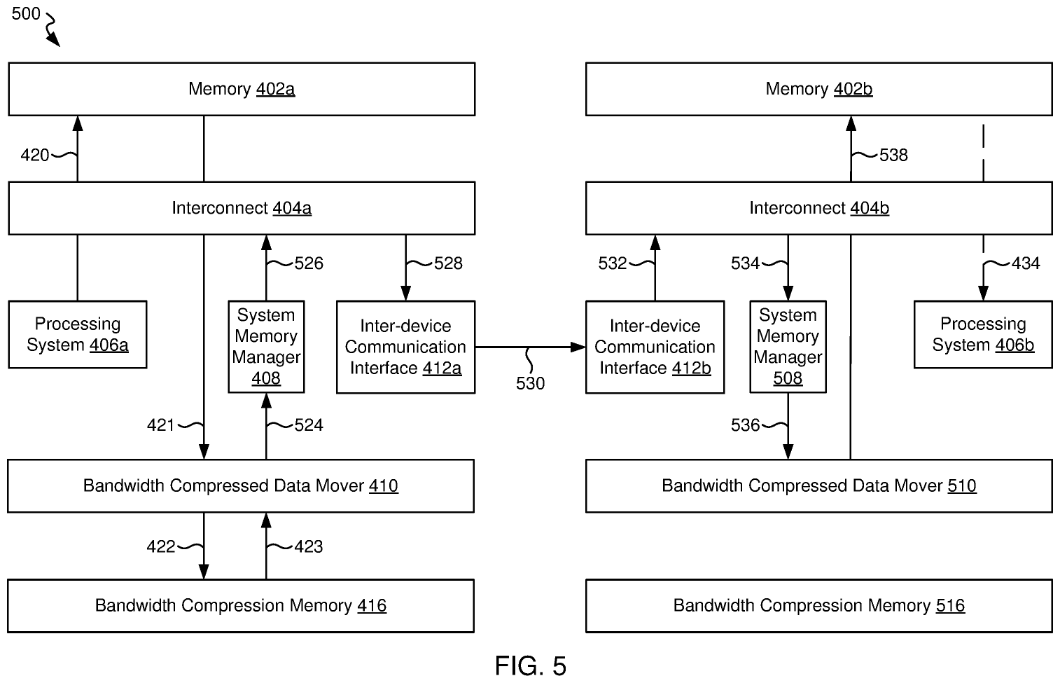

In the example illustrated in FIG. 5, the bandwidth compressed data movement system 500 may be configured to serialize the valid bandwidth compressed data and to write the serialized valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device. For example, the output device may be the memory 402b or the processing system 406b. In some embodiments, the bandwidth compressed data movement system 500 may be configured to compress the serialized valid bandwidth compressed data and to write the compressed serialized valid bandwidth compressed data to the output device.

The bandwidth compressed data mover 410 may implement a process 524 transmitting the serialized valid bandwidth compressed data and associated metadata to the system memory manager 408. The system memory manager 408 may implement a process 526 transmitting the serialized valid bandwidth compressed data and associated metadata to the interconnect 404a. The interconnect 404a may implement a process 528 transmitting the serialized valid bandwidth compressed data and associated metadata to an inter-device communication interface 412a (e.g., peripheral device interface 38 in FIG. 1). In some embodiments, the bandwidth compressed data mover 410 may include a virtual address data buffer (not shown) mapped to the inter-device communication interface 412a to enable writing across the inter-device communication interface 412a. The inter-device communication interface 412a may implement a process 530 transmitting the serialized valid bandwidth compressed data and associated metadata to the inter-device communication interface 412b. In some embodiments, the processes 524-530 may be similarly implemented for the compressed serialized valid bandwidth compressed data.

The inter-device communication interface 412b may implement a process 532 transmitting the serialized valid bandwidth compressed data and associated metadata to the interconnect 404b. The interconnect 404b process 532 transmitting the serialized valid bandwidth compressed data and associated metadata to the system memory manager 534. The system memory manager 534 may implement a process 536 transmitting the serialized valid bandwidth compressed data and associated metadata to the bandwidth compressed data mover 510. In some embodiments, the processes 532-536 may be similarly implemented for the compressed serialized valid bandwidth compressed data.

The bandwidth compressed data mover 510 may implement a process 538 transmitting valid bandwidth compressed data to the memory 402b where the valid bandwidth compressed data and associated metadata may be stored. The bandwidth compressed data mover 510 may implement the process 538 by decoding the serialized bandwidth compressed data using the associated metadata. The bandwidth compressed data mover 510 may decode the serialized bandwidth compressed data by deserialization generating the valid bandwidth compressed data. In some embodiments, the prior to decoding the serialized bandwidth compressed data, the bandwidth compressed data mover 510 may implement the process 538 by decoding the compressed serialized bandwidth compressed data using the associated metadata. The bandwidth compressed data mover 510 may decode the compressed serialized bandwidth compressed data by decompression generating the serialized valid bandwidth compressed data. In some embodiments, the memory 402b may optionally implement a process 434 transmitting the valid bandwidth compressed data and associated metadata to the processing system 406b.

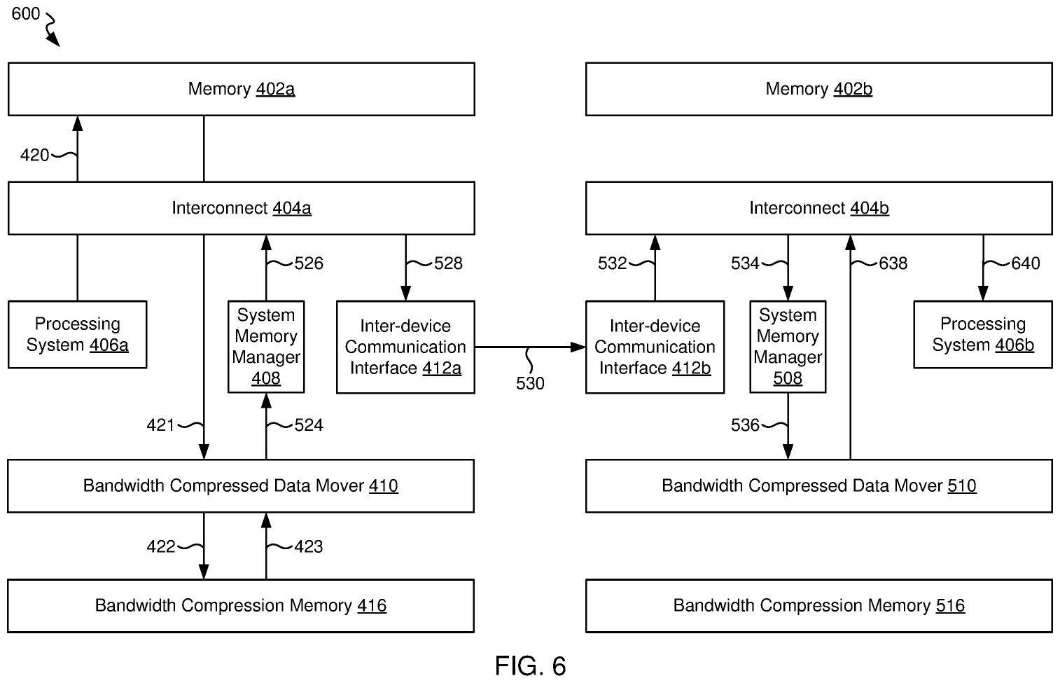

In the example illustrated in FIG. 6, the bandwidth compressed data movement system 600 may be configured to serialize the valid bandwidth compressed data and to write the serialized valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device. For example, the output device may be the processing system 406b. In some embodiments, the bandwidth compressed data movement system 600 may be configured to compress the serialized valid bandwidth compressed data and to write the compressed serialized valid bandwidth compressed data to the output device. Processes 524-536 may be implemented similarly as described with reference to FIG. 5.

The bandwidth compressed data mover 510 may implement a process 638 transmitting valid bandwidth compressed data to the interconnect 404b. The bandwidth compressed data mover 510 may implement the process 638 by decoding the serialized bandwidth compressed data using the associated metadata. The bandwidth compressed data mover 510 may decode the serialized bandwidth compressed data by deserialization generating the valid bandwidth compressed data. In some embodiments, the prior to decoding the serialized bandwidth compressed data, the bandwidth compressed data mover 510 may implement the process 638 by decoding the compressed serialized bandwidth compressed data using the associated metadata. The bandwidth compressed data mover 510 may decode the compressed serialized bandwidth compressed data by decompression generating the serialized valid bandwidth compressed data. The interconnect 404b may implement a process 640 transmitting the valid bandwidth compressed data and associated metadata to the processing system 406b.

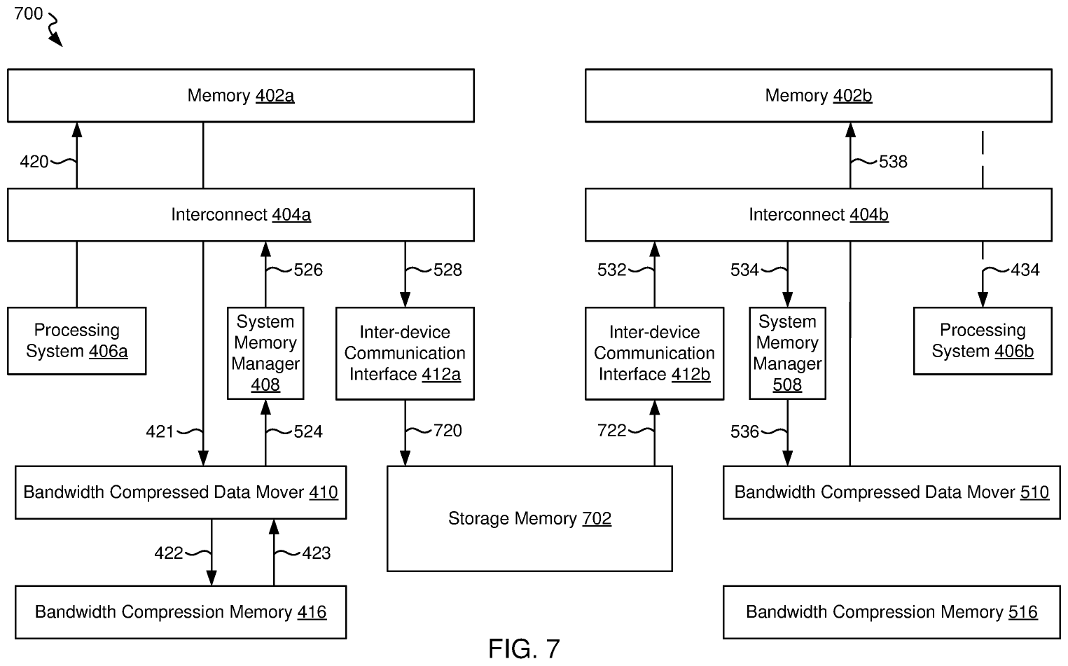

In the example illustrated in FIG. 7, the bandwidth compressed data movement system 700 may be configured to serialize the valid bandwidth compressed data and to write the serialized valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device. For example, the output device may be a storage memory 702 (e.g., storage memory 24 in FIG. 1). In some embodiments, the bandwidth compressed data movement system 700 may be configured to compress the serialized valid bandwidth compressed data and to write the compressed serialized valid bandwidth compressed data to the output device. Processes 524-528, 532-538, and 434 may be implemented similarly as described with reference to FIG. 5.

An inter-device communication interface 412a (e.g., storage memory interface 20, peripheral device interface 38 in FIG. 1) may implement a process 720 transmitting the serialized valid bandwidth compressed data and associated metadata to a storage memory 702 (e.g., storage memory 24 in FIG. 1). The storage memory 702 may store the serialized valid bandwidth compressed data and associated metadata. The serialized valid bandwidth compressed data may be stored as serialized valid bandwidth compressed data, rather than decoding the serialized valid bandwidth compressed data and storing the resultant valid bandwidth compressed data. In some embodiments, the process 720 may be similarly implemented for the compressed serialized valid bandwidth compressed data. The storage memory 702 may store the compressed serialized valid bandwidth compressed data and associated metadata. The compressed serialized valid bandwidth compressed data may be stored as compressed serialized valid bandwidth compressed data.

In some embodiments, in response to a memory access command, the storage memory 702 may implement a process 722 transmitting the serialized valid bandwidth compressed data and associated metadata to an inter-device communication interface 412b (e.g., storage memory interface 20, peripheral device interface 38 in FIG. 1). In some embodiments, the process 722 may be similarly implemented for the compressed serialized valid bandwidth compressed data.

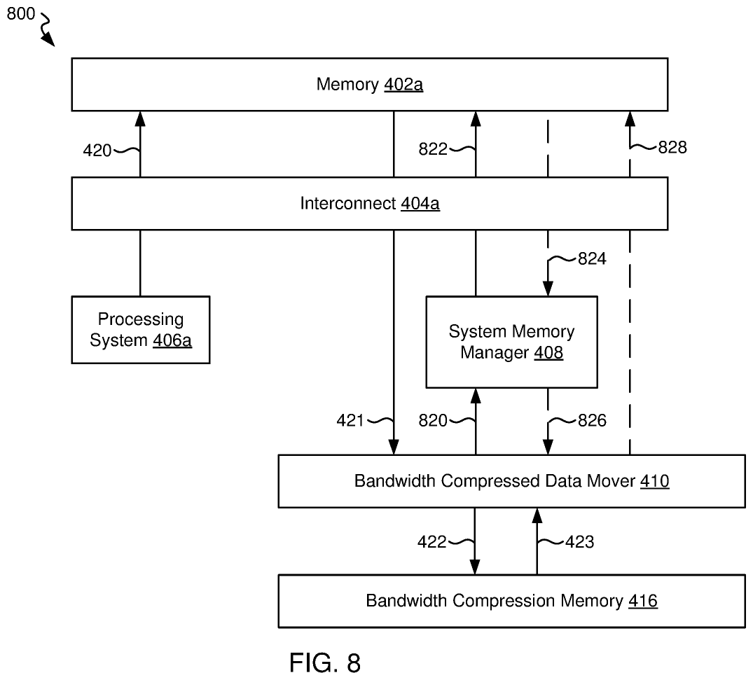

In the example illustrated in FIG. 8, the bandwidth compressed data movement system 800 may be configured to serialize the valid bandwidth compressed data and to write the serialized valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device. For example, the output device may be the memory 402a. In some embodiments, the bandwidth compressed data movement system 800 may be configured to compress the serialized valid bandwidth compressed data and to write the compressed serialized valid bandwidth compressed data to the output device.

The bandwidth compressed data mover 410 may implement a process 820 transmitting the serialized valid bandwidth compressed data and associated metadata to the system memory manager 408. The system memory manager 408 may implement a process 822 transmitting the serialized valid bandwidth compressed data and associated metadata to the memory 402a. The memory 402a may store the serialized valid bandwidth compressed data and associated metadata. The serialized valid bandwidth compressed data may be stored as serialized valid bandwidth compressed data, rather than decoding the serialized valid bandwidth compressed data and storing the resultant valid bandwidth compressed data. In some embodiments, the processes 820 and 822 may be similarly implemented for the compressed serialized valid bandwidth compressed data. The memory 402a may store the compressed serialized valid bandwidth compressed data and associated metadata. The compressed serialized valid bandwidth compressed data may be stored as compressed serialized valid bandwidth compressed data.

In some embodiments, in response to a memory access command, the memory 402a may implement a process 824 transmitting the serialized valid bandwidth compressed data and associated metadata to the system memory manager 408. The system memory manager 408 may implement a process 826 transmitting the serialized valid bandwidth compressed data and associated metadata to the bandwidth compressed data mover 410. The bandwidth compressed data mover 410 may implement a process 828 transmitting valid bandwidth compressed data and associated metadata to the memory 402a. The bandwidth compressed data mover 410 may implement the process 828 further by decoding the serialized valid bandwidth compressed data using associated metadata resulting in the valid bandwidth compressed data. In some embodiments, the processes 824-828 may be similarly implemented for the compressed serialized valid bandwidth compressed data.

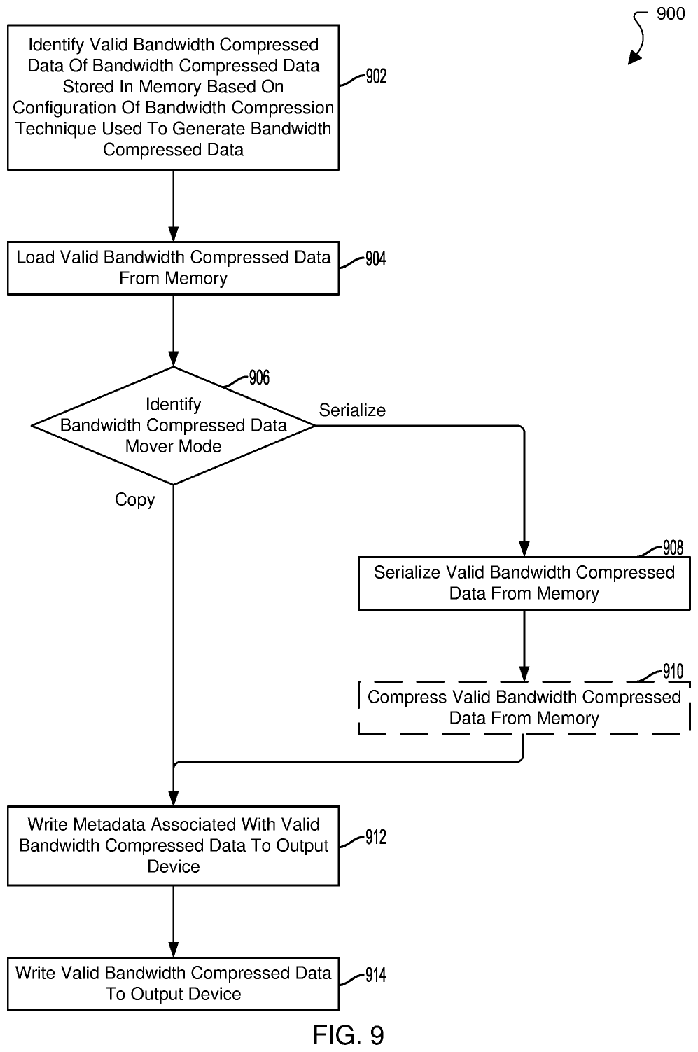

FIG. 9 illustrates an example method for implementing bandwidth compressed data movement according to an embodiment. With reference to FIGS. 1-9, the method 900 may be implemented in a computing device (e.g., computing device 10, 300 in FIGS. 1 and 3), in hardware (e.g., bandwidth compressed data mover 200, 410a, 410b in FIGS. 2 and 4-8, modules 202-216 in FIG. 2), in software executing in a processing system (e.g., processing system 14, 304 in FIGS. 1 and 3), or in a combination of a software-configured processor and dedicated hardware, that includes other individual components, such as various memories/caches (e.g., memory 16, 36, 302 in FIGS. 1 and 3). In order to encompass the alternative configurations enabled in various embodiments, the hardware implementing the method 900 is referred to herein as a “bandwidth compressed data mover device.”

In block 902, the bandwidth compressed data mover device may identify valid bandwidth compressed data of bandwidth compressed data stored in a memory (e.g., memory 16, 36, 402a, 402b in FIGS. 1 and 4-8). In some embodiments, the bandwidth compressed data mover device identifying the valid bandwidth compressed data of the bandwidth compressed data stored in the memory in block 902 may be a processing system (e.g., processing system 14, 304 in FIGS. 1 and 3), a bandwidth compressed data mover (e.g., bandwidth compressed data mover 200, 306, 410a, 410b in FIGS. 2-8), and/or a module (e.g., metadata module 202, data reader module 204 in FIGS. 2 and 3).

The valid bandwidth compressed data may be identified based on a configuration of a bandwidth compression technique used to generate the bandwidth compressed data. In some embodiments, the valid bandwidth compressed data may be identified based further on metadata associated with the bandwidth compressed data in the memory. In some embodiments, the valid bandwidth compressed data may be identified based further on speculative access of the bandwidth compressed data stored in the memory. For example, the bandwidth compressed data mover device may use knowledge of how the bandwidth compressed data is generated to identify which portions of the bandwidth compressed data are valid bandwidth compressed data. As another example, the bandwidth compressed data mover device may additionally use information such as location and size of the bandwidth compressed data in the memory from the metadata to identify which portions of the bandwidth compressed data are valid bandwidth compressed data.

Identifying the valid bandwidth compressed data may include identifying an address at which the valid bandwidth compressed data is stored in the memory. Identifying the valid bandwidth compressed data may also include identifying a size of the valid bandwidth compressed data stored in the memory.

In some embodiments, the bandwidth compressed data mover device may identify a number of different valid bandwidth compressed data. How many different valid bandwidth compressed data may be identified may be based on a predetermined or dynamic efficiency granularity. For example, the efficiency granularity may be based on a multiple of the memory access length of the memory at which the bandwidth compressed data is stored.

In block 904, the bandwidth compressed data mover device may load the valid bandwidth compressed data from the memory. The valid bandwidth compressed data may be retrieved from the memory using the address or the size of the valid bandwidth compressed data stored in the memory. In some embodiments, the valid bandwidth compressed data may be retrieved from a speculation memory (e.g., memory 16, 36, 302, 402a, 402b, 416, 516 in FIGS. 1 and 4-8) in which mis-speculated valid bandwidth compressed data may be stored using the address or the size of the valid bandwidth compressed data stored in the speculation memory. In some embodiments, the bandwidth compressed data mover device may load the number of different identified valid bandwidth compressed data. In some embodiments, the bandwidth compressed data mover device loading the valid bandwidth compressed data from the memory in block 904 may be the processing system, the bandwidth compressed data mover, and/or a module (e.g., data reader module 204 in FIGS. 2 and 3).

In determination block 906, the bandwidth compressed data mover device may identify a bandwidth compressed data mover mode. The bandwidth compressed data mover mode may be whether the bandwidth compressed data mover is configured to copy the valid bandwidth compressed data or serialize the valid bandwidth compressed data. The bandwidth compressed data mover device may read and interpret a configuration signal having a value configured to indicate to copy or to serialize the valid bandwidth compressed data. The bandwidth compressed data mover device may receive the configuration signal as part of a memory access request or retrieve the configuration signal from the configuration memory, such as a register, an electronic fuse (or eFuse), a pin, etc. In some embodiments, the bandwidth compressed data mover device identifying the bandwidth compressed data mover mode in block 906 may be the processing system, the bandwidth compressed data mover, and/or a module (e.g., data serializer module 206 in FIGS. 2 and 3).

In response to identifying that the bandwidth compressed data mover mode is to serialize the valid bandwidth compressed data (i.e., determination block 906=“Serialize”), the bandwidth compressed data mover device may serialize the valid bandwidth compressed data in block 908. In some embodiments, the bandwidth compressed data mover device serializing the valid bandwidth compressed data in block 908 may be the processing system, the bandwidth compressed data mover, and/or a module (e.g., data serializer module 206 in FIGS. 2 and 3).

The bandwidth compressed data mover device may serialize the valid bandwidth compressed data by formatting the valid bandwidth compressed data as a stream of data. For example, the valid bandwidth compressed data may be compacted by rearranging the valid bandwidth compressed data. The valid bandwidth compressed data may be rearranged in a manner reducing, even eliminating, unused space between the valid bandwidth compressed data. The unused space between the valid bandwidth compressed data may be space created by not retrieving invalid bandwidth compressed data.

The bandwidth compressed data mover device may also generate metadata associated with the serialized valid bandwidth compressed data configured to enable decoding, by deserialization, of the serialized valid bandwidth compressed data. For example, the metadata associated with the serialized valid bandwidth compressed data may include sizes for the portions of the serialized valid bandwidth compressed data. The metadata associated with the serialized valid bandwidth compressed data may also include spacing between the portions of the serialized valid bandwidth compressed data.

In optional block 910, the bandwidth compressed data mover device may compress the valid bandwidth compressed data. In some embodiments, the bandwidth compressed data mover device compressing the valid bandwidth compressed data in optional block 910 may be the processing system, the bandwidth compressed data mover, and/or a module (e.g., data compression module 208 in FIGS. 2 and 3).

The bandwidth compressed data mover device may optionally be configured to compress serialized valid bandwidth compressed data. Compressing the serialized valid bandwidth compressed data may be use case specific. For example, compressing the serialized valid bandwidth compressed data may be implemented based on a type of data of the serialized valid bandwidth compressed data. The type of data may be larger scale redundant information. As another example, compressing the serialized valid bandwidth compressed data may be implemented based on writing the valid bandwidth compressed data to an output device (e.g., SoC 12, processing system 14, memory 16, communication interface 18, storage memory interface 20, memory interface 34, peripheral device interface 38, communication component 22, storage memory 24, memory 36, peripheral device 40 in FIG. 1) of the computing device having a bandwidth compressed data mover device. As another example, compressing the serialized valid bandwidth compressed data may be implemented based on writing the compressed serialized valid bandwidth compressed data to a memory (e.g., memory 16, 36, storage memory 24 in FIG. 1), including the memory in which the valid bandwidth compressed data is stored.

The bandwidth compressed data mover device may also generate metadata associated with the compressed serialized valid bandwidth compressed data configured to enable decoding, by decompression, of the compressed serialized valid bandwidth compressed data. For example, the metadata associated with the compressed serialized valid bandwidth compressed data may include details of the valid bandwidth compressed data compression, such as size of the compressed serialized valid bandwidth compressed data, compression algorithm identifier, compression parameters, etc.

In response to identifying that the bandwidth compressed data mover mode is to copy the valid bandwidth compressed data (i.e., determination block 906=“Copy”); or following serializing the valid bandwidth compressed data in block 908; or following compressing the valid bandwidth compressed data in optional block 910, the bandwidth compressed data mover device may write the metadata associated with the valid bandwidth compressed data to the output device in block 912. In some embodiments, the bandwidth compressed data mover device writing the metadata associated with the valid bandwidth compressed data to the output device in block 912 may be the processing system, the bandwidth compressed data mover, and/or a module (e.g., data transmitter module 210 in FIGS. 2 and 3). The bandwidth compressed data mover device may be configured to transmit the metadata to the output device targeted by the memory access command.

The metadata may include the metadata associated with any format of valid bandwidth compressed data. For example, the metadata may include metadata associated with the valid bandwidth compressed data and retrieved from the memory in block 902. As another example, the metadata may include metadata generated for valid bandwidth compressed data not associated with metadata in the memory. As another example, the metadata may include metadata data generated for and associated with serialized valid bandwidth compressed data in block 908. As another example, the metadata may include metadata data generated for and associated with compressed serialized valid bandwidth compressed data in block 910.

In block 914, the bandwidth compressed data mover device may write the valid bandwidth compressed data to the output device. In some embodiments, the bandwidth compressed data mover device writing the valid bandwidth compressed data to the output device in block 914 may be the processing system, the bandwidth compressed data mover, and/or a module (e.g., data transmitter module 210 in FIGS. 2 and 3). The bandwidth compressed data mover device may be configured to transmit the valid bandwidth compressed data to the output device targeted by the memory access command.

The bandwidth compressed data mover device may be configured to transmit the valid bandwidth compressed data in any format. For example, the valid bandwidth compressed data transmitted may be the valid bandwidth compressed data retrieved from the memory in block 904. As another example, the valid bandwidth compressed data may be the serialized valid bandwidth compressed data serialized in block 908. As another example, the valid bandwidth compressed data may be the compressed serialized valid bandwidth compressed data compressed in optional block 910. In some embodiments, the output device may be the same memory from which the valid bandwidth compressed data is retrieved in block 904.

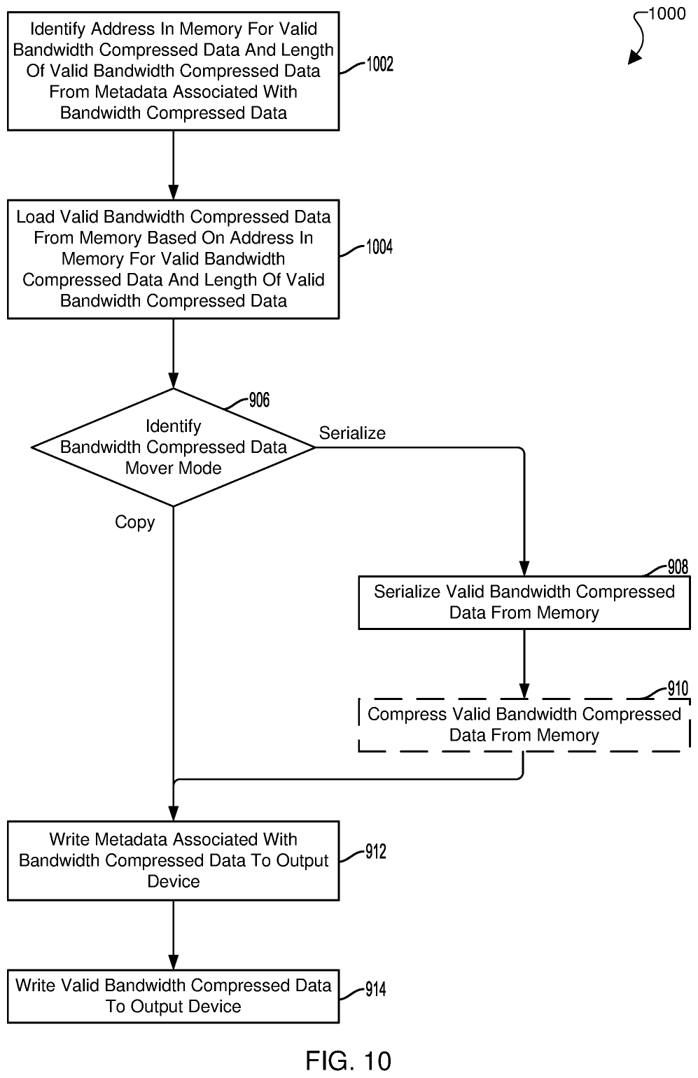

FIG. 10 illustrates an example method for implementing bandwidth compressed data movement for bandwidth compressed data having associated metadata according to an embodiment. With reference to FIGS. 1-10, the method 1000 may be implemented in a computing device (e.g., computing device 10, 300 in FIGS. 1 and 3), in hardware (e.g., bandwidth compressed data mover 200, 410a, 410b in FIGS. 2 and 4-8, modules 202-216 in FIG. 2), in software executing in a processing system (e.g., processing system 14, 304 in FIGS. 1 and 3), or in a combination of a software-configured processor and dedicated hardware, that includes other individual components, such as various memories/caches (e.g., memory 16, 36, 302 in FIGS. 1 and 3). In order to encompass the alternative configurations enabled in various embodiments, the hardware implementing the method 1000 is referred to herein as a “bandwidth compressed data mover device.”

In block 1002, the bandwidth compressed data mover device may identify valid bandwidth compressed data of bandwidth compressed data stored in a memory (e.g., memory 16, 36, 402a, 402b in FIGS. 1 and 4-8). In some embodiments, the bandwidth compressed data mover device identifying the valid bandwidth compressed data of the bandwidth compressed data stored in the memory in block 1002 may be a processing system (e.g., processing system 14, 304 in FIGS. 1 and 3), a bandwidth compressed data mover (e.g., bandwidth compressed data mover 200, 306, 410a, 410b in FIGS. 2-8), and/or a module (e.g., metadata module 202, data reader module 204 in FIGS. 2 and 3).

The valid bandwidth compressed data may be identified based on a configuration of a bandwidth compression technique used to generate the bandwidth compressed data and on metadata associated with the bandwidth compressed data in the memory. The bandwidth compressed data mover device may use knowledge of how the bandwidth compressed data is generated to identify which portions of the bandwidth compressed data are valid bandwidth compressed data. The bandwidth compressed data mover device may additionally use information such as location and size of the bandwidth compressed data in the memory from the metadata to identify which portions of the bandwidth compressed data are valid bandwidth compressed data. Identifying the valid bandwidth compressed data may include identifying an address at which the valid bandwidth compressed data is stored in the memory. Identifying the valid bandwidth compressed data may also include identifying a size of the valid bandwidth compressed data stored in the memory.

In some embodiments, the bandwidth compressed data mover device may identify a number of different valid bandwidth compressed data. How many different valid bandwidth compressed data may be identified may be based on a predetermined or dynamic efficiency granularity. For example, the efficiency granularity may be based on a multiple of the memory access length of the memory at which the bandwidth compressed data is stored.

In block 1004, the bandwidth compressed data mover device may load the valid bandwidth compressed data from the memory. The valid bandwidth compressed data may be retrieved from the memory using the address or the size of the valid bandwidth compressed data stored in the memory. In some embodiments, the bandwidth compressed data mover device may load the number of different identified valid bandwidth compressed data. In some embodiments, the bandwidth compressed data mover device loading the valid bandwidth compressed data from the memory in block 1004 may be the processing system, the bandwidth compressed data mover, and/or a module (e.g., data reader module 204 in FIGS. 2 and 3).

Determination block 906, block 908, optional block 910, block 912, and block 914 may be implemented similarly as in the method 900 described with reference to FIG. 9.

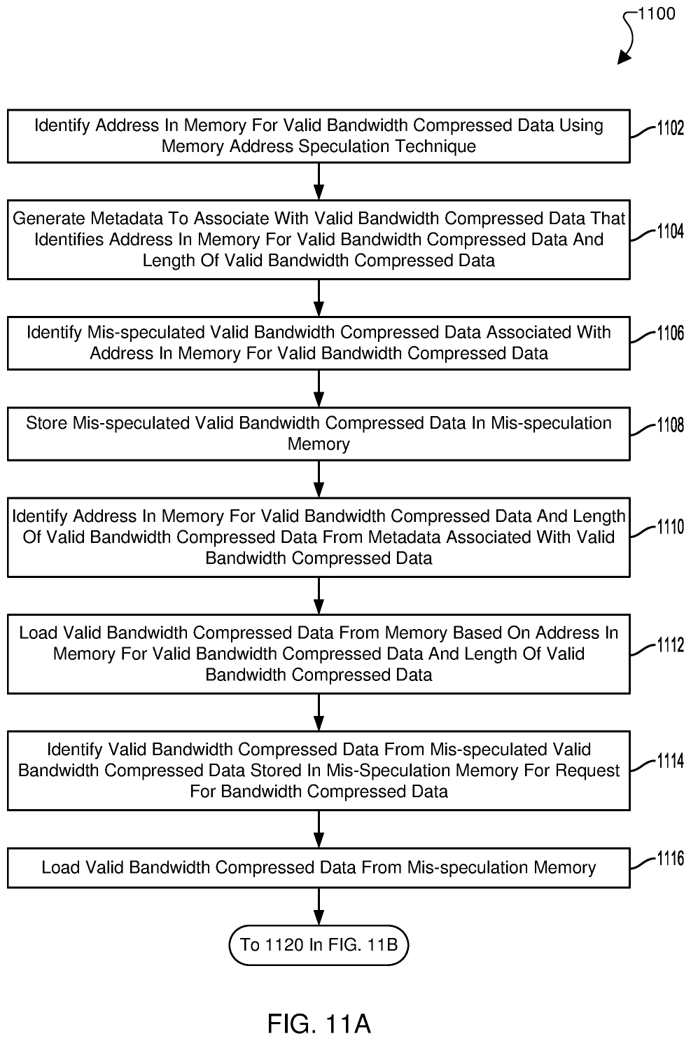

FIGS. 11A and 11B illustrate an example method for implementing bandwidth compressed data movement for bandwidth compressed data without associated metadata according to an embodiment. With reference to FIGS. 1-11, the method 1100 may be implemented in a computing device (e.g., computing device 10, 300 in FIGS. 1 and 3), in hardware (e.g., bandwidth compressed data mover 200, 410a, 410b in FIGS. 2 and 4-8, modules 202-216 in FIG. 2), in software executing in a processing system (e.g., processing system 14, 304 in FIGS. 1 and 3), or in a combination of a software-configured processor and dedicated hardware, that includes other individual components, such as various memories/caches (e.g., memory 16, 36, 302 in FIGS. 1 and 3). In order to encompass the alternative configurations enabled in various embodiments, the hardware implementing the method 1100 is referred to herein as a “bandwidth compressed data mover device.”

In block 1102, the bandwidth compressed data mover device may identify valid bandwidth compressed data of bandwidth compressed data stored in a memory (e.g., memory 16, 36, 402a, 402b in FIGS. 1 and 4-8). In some embodiments, the bandwidth compressed data mover device identifying the valid bandwidth compressed data of the bandwidth compressed data stored in the memory in block 1102 may be a processing system (e.g., processing system 14, 304 in FIGS. 1 and 3), a bandwidth compressed data mover (e.g., bandwidth compressed data mover 200, 306, 410a, 410b in FIGS. 2-8), and/or a module (e.g., metadata module 202, data reader module 204 in FIGS. 2 and 3).

The valid bandwidth compressed data may be identified based on a configuration of a bandwidth compression technique used to generate the bandwidth compressed data. In some embodiments, the valid bandwidth compressed data may be identified based further on speculative access of the bandwidth compressed data stored in the memory. Speculative access of bandwidth compressed data may be implemented for bandwidth compressed data not having associated metadata. Speculative access of bandwidth compressed data may be based on one or more memory address speculation techniques, such as prediction, probing and checking, etc. The speculative access may be informed by the configuration of the bandwidth compression technique to identify valid bandwidth compression data. For example, the bandwidth compressed data mover device may use knowledge of how the bandwidth compressed data is generated to identify which portions of the bandwidth compressed data are valid bandwidth compressed data. Identifying the valid bandwidth compressed data may include identifying an address at which the valid bandwidth compressed data is stored in the memory. Identifying the valid bandwidth compressed data may also include identifying a size of the valid bandwidth compressed data stored in the memory.

In some embodiments, the bandwidth compressed data mover device may identify a number of different valid bandwidth compressed data. How many different valid bandwidth compressed data may be identified may be based on a predetermined or dynamic efficiency granularity. For example, the efficiency granularity may be based on a multiple of the memory access length of the memory at which the bandwidth compressed data is stored.

In block 1104, the bandwidth compressed data mover device may generate metadata and associate the metadata with bandwidth compressed data for which there is no associated metadata. In some embodiments, the bandwidth compressed data mover device generating the metadata and associating the metadata with the bandwidth compressed data for which there is no associated metadata in block 1104 may be the processing system, the bandwidth compressed data mover, and/or a module (e.g., metadata module 202 in FIGS. 2 and 3).

Metadata may be generated for and associated with bandwidth compressed data for which there is no associated metadata. The metadata may be generated for bandwidth compressed data that may be speculatively accessed. The metadata may be generated for and associated with the speculatively accessed bandwidth compressed data based on the speculative access and the configuration of the bandwidth compression technique used to generate the bandwidth compressed data. The address of the speculative access of the bandwidth compressed data and knowledge of how data is converted to bandwidth compressed data may be used to generate an address and length of the bandwidth compressed data. The metadata may be associated with the speculatively accessed bandwidth compressed data.

Metadata may be generated and associated with the valid bandwidth compressed data of the speculatively accessed bandwidth compressed data. The metadata may be generated and associated with the valid bandwidth compressed data based on the speculative access and the configuration of the bandwidth compression technique used to generate the bandwidth compressed data. For example, the size of the valid bandwidth compressed data may be calculated. The size of the valid bandwidth compressed data may be identified for or calculated for the valid bandwidth compressed data based on the metadata associated with the bandwidth compressed data and a configuration of a bandwidth compression technique used to generate the bandwidth compressed data.

The address and length of the bandwidth compressed data and knowledge of how data is converted to bandwidth compressed data to identify or calculate an address and length of the valid bandwidth compressed data. For example, knowledge of how data is converted to bandwidth compressed data may include the compression scheme, compression ratio, etc. that may be indicative of characteristics of the bandwidth compressed data resultant from the bandwidth compression technique. The address of the speculative access of the bandwidth compressed data and knowledge of how data is converted to bandwidth compressed data may be used to generate an address and length of the valid bandwidth compressed data. The metadata may be associated with the valid bandwidth compressed data of the speculatively accessed bandwidth compressed data.

In block 1106, the bandwidth compressed data mover device may identify mis-speculated valid bandwidth compressed data. The valid bandwidth compressed data identified in block 1102 may be checked for relevance for a memory access request. Irrelevant valid bandwidth compressed data may be identified as mis-speculated. In some embodiments, the bandwidth compressed data mover device identifying the mis-speculated bandwidth compressed data in block 1106 may be the processing system, the bandwidth compressed data mover, and/or a module (e.g., metadata module 202 in FIGS. 2 and 3).

In block 1108, the bandwidth compressed data mover device may store the mis-speculated valid bandwidth compressed data in a speculation memory (e.g., memory 16, 36, 302, 402a, 402b, 416, 516 in FIGS. 1 and 4-8). The mis-speculated valid bandwidth compressed data and the associated metadata may be stored in the speculation memory. In some embodiments, the bandwidth compressed data mover device storing the mis-speculated valid bandwidth compressed data in the speculation memory in block 1108 may be the processing system, the bandwidth compressed data mover, and/or a module (e.g., metadata module 202 in FIGS. 2 and 3).

In block 1110, the bandwidth compressed data mover device may identify the valid bandwidth compressed data of bandwidth compressed data stored in the memory. In some embodiments, the bandwidth compressed data mover device identifying the valid bandwidth compressed data of the bandwidth compressed data stored in the memory in block 1110 may be a processing system (e.g., processing system 14, 304 in FIGS. 1 and 3), a bandwidth compressed data mover (e.g., bandwidth compressed data mover 200, 306, 410a, 410b in FIGS. 2-8), and/or a module (e.g., metadata module 202, data reader module 204 in FIGS. 2 and 3).

The valid bandwidth compressed data may be identified based on metadata associated with the valid bandwidth compressed data in the memory. For example, the bandwidth compressed data mover device may use information such as location and size of the valid bandwidth compressed data in the memory from the metadata to identify the valid bandwidth compressed data. Identifying the valid bandwidth compressed data may include identifying an address at which the valid bandwidth compressed data is stored in the memory. Identifying the valid bandwidth compressed data may also include identifying a size of the valid bandwidth compressed data stored in the memory.

In some embodiments, the bandwidth compressed data mover device may identify a number of different valid bandwidth compressed data. How many different valid bandwidth compressed data may be identified may be based on a predetermined or dynamic efficiency granularity. For example, the efficiency granularity may be based on a multiple of the memory access length of the memory at which the bandwidth compressed data is stored.

In block 1112, the bandwidth compressed data mover device may load the valid bandwidth compressed data from the memory. The valid bandwidth compressed data may be retrieved from the memory using the address or the size of the valid bandwidth compressed data stored in the memory. In some embodiments, the bandwidth compressed data mover device may load the number of different identified valid bandwidth compressed data. In some embodiments, the bandwidth compressed data mover device loading the valid bandwidth compressed data from the memory in block 1112 may be the processing system, the bandwidth compressed data mover, and/or a module (e.g., data reader module 204 in FIGS. 2 and 3).

In block 1114, the bandwidth compressed data mover device may identify valid bandwidth compressed data of the mis-speculated valid bandwidth compressed data stored in the speculation memory. In some embodiments, the bandwidth compressed data mover device identifying the valid bandwidth compressed data of the bandwidth compressed data of the mis-speculated valid bandwidth compressed data stored in the speculation memory in block 1114 may be the processing system, the bandwidth compressed data mover, and/or a module (e.g., metadata module 202, data reader module 204 in FIGS. 2 and 3).

The valid bandwidth compressed data may be identified based on the metadata associated with the valid bandwidth compressed data in the speculation memory. The bandwidth compressed data mover device may use information such as location and size of the valid bandwidth compressed data in the speculation memory from the metadata to identify the valid bandwidth compressed data. Identifying the valid bandwidth compressed data may include identifying an address at which the valid bandwidth compressed data is stored in the speculation memory. Identifying the valid bandwidth compressed data may also include identifying a size of the valid bandwidth compressed data stored in the speculation memory.

In some embodiments, the bandwidth compressed data mover device may identify a number of different valid bandwidth compressed data. How many different valid bandwidth compressed data may be identified may be based on a predetermined or dynamic efficiency granularity. For example, the efficiency granularity may be based on a multiple of the memory access length of the memory at which the bandwidth compressed data is stored.

In block 1116, the bandwidth compressed data mover device may load the valid bandwidth compressed data of the mis-speculated valid bandwidth compressed data stored in the speculation memory. The valid bandwidth compressed data may be retrieved from the speculation memory using the address or the size of the valid bandwidth compressed data stored in the speculation memory. In some embodiments, the valid bandwidth compressed data may be retrieved from the speculation memory in which mis speculated valid bandwidth compressed data may be stored using the address or the size of the valid bandwidth compressed data stored in the speculation memory. In some embodiments, the bandwidth compressed data mover device may load the number of different identified valid bandwidth compressed data. In some embodiments, the bandwidth compressed data mover device loading the valid bandwidth compressed data of the mis-speculated valid bandwidth compressed data stored in the speculation memory in block 1116 may be the processing system, the bandwidth compressed data mover, and/or a module (e.g., data reader module 204 in FIGS. 2 and 3).

Determination block 906, block 908, optional block 910, block 912, and block 914 may be implemented similarly as in the method 900 described with reference to FIG. 9.

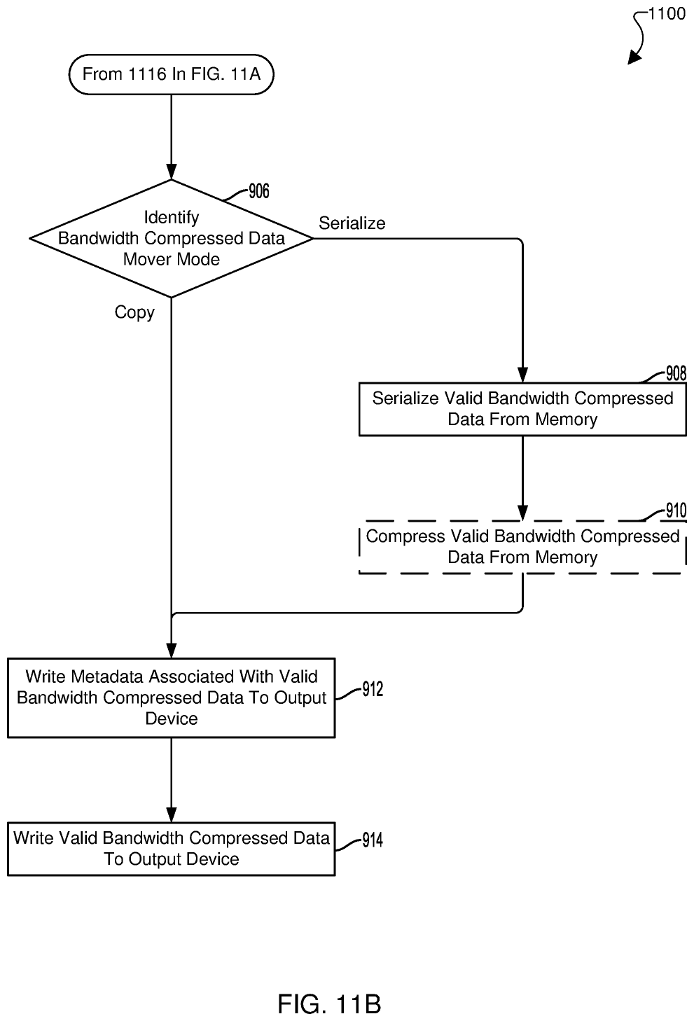

A system in accordance with the various embodiments (including, but not limited to, embodiments described above with reference to FIGS. 1-11) may be implemented in a wide variety of computing systems including mobile computing devices, an example of which suitable for use with the various embodiments is illustrated in FIG. 12. The mobile computing device 1200 may include a processor 1202 coupled to a touchscreen controller 1204 and an internal memory 1206. The processor 1202 may be one or more multicore integrated circuits designated for general or specific processing tasks. The internal memory 1206 may be volatile or non-volatile memory, and may also be secure and/or encrypted memory, unsecure and/or unencrypted memory, or any combination thereof. Examples of memory types that can be leveraged include but are not limited to DDR, Low-Power DDR (LPDDR), Graphics DDR (GDDR), WIDEIO, RAM, Static RAM (SRAM), Dynamic RAM (DRAM), Parameter RAM (P-RAM), Resistive RAM (R-RAM), Magnetoresistive RAM (M-RAM), Spin-Transfer Torque RAM (STT-RAM), and embedded DRAM. The touchscreen controller 1204 and the processor 1202 may also be coupled to a touchscreen panel 1212, such as a resistive-sensing touchscreen, capacitive-sensing touchscreen, infrared sensing touchscreen, etc. Additionally, the display of the mobile computing device 1200 need not have touch screen capability.

The mobile computing device 1200 may have one or more radio signal transceivers 1208 (e.g., Peanut, Bluetooth, ZigBee, Wi-Fi, RF radio) and antennae 1210, for sending and receiving communications, coupled to each other and/or to the processor 1202. The processor 1202 may also be coupled to a cellular network wireless modem 1209 that enables communication via a cellular network (e.g., a 5G network) via the antenna 1210. The transceivers 1208 and antennae 1210 may be used with the above-mentioned circuitry to implement the various wireless transmission protocol stacks and interfaces.

The mobile computing device 1200 may include a peripheral device connection interface 1218 coupled to the processor 1202. The peripheral device connection interface 1218 may be singularly configured to accept one type of connection, or may be configured to accept various types of physical and communication connections, common or proprietary, such as Universal Serial Bus (USB), FireWire, Thunderbolt, or PCIe. The peripheral device connection interface 1218 may also be coupled to a similarly configured peripheral device connection port (not shown).

The mobile computing device 1200 may also include speakers 1214 for providing audio outputs. The mobile computing device 1200 may also include a housing 1220, constructed of a plastic, metal, or a combination of materials, for containing all or some of the components described herein. The mobile computing device 1200 may include a power source 1222 coupled to the processor 1202, such as a disposable or rechargeable battery. The rechargeable battery may also be coupled to the peripheral device connection port to receive a charging current from a source external to the mobile computing device 1200. The mobile computing device 1200 may also include a physical button 1224 for receiving user inputs. The mobile computing device 1200 may also include a power button 1226 for turning the mobile computing device 1200 on and off.

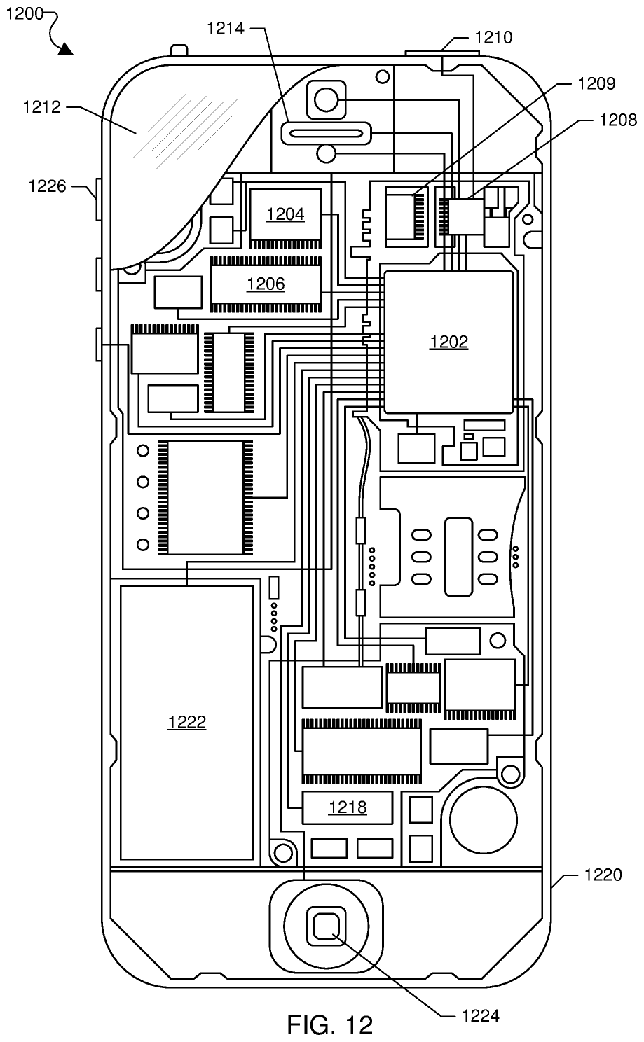

A system in accordance with the various embodiments (including, but not limited to, embodiments described above with reference to FIGS. 1-11) may be implemented in a wide variety of computing systems including a laptop computer 1300, an example of which is illustrated in FIG. 13. Many laptop computers include a touchpad touch surface 1317 that serves as the computer's pointing device, and thus may receive drag, scroll, and flick gestures similar to those implemented on computing devices equipped with a touch screen display and described above. A laptop computer 1300 will typically include a processor 1302 coupled to volatile memory 1312 and a large capacity nonvolatile memory, such as a disk drive 1313 of Flash memory. Additionally, the computer 1300 may have one or more antenna 1308 for sending and receiving electromagnetic radiation that may be connected to a wireless data link and/or cellular telephone transceiver 1316 coupled to the processor 1302. The computer 1300 may also include a floppy disc drive 1314 and a compact disc (CD) drive 1315 coupled to the processor 1302. In a notebook configuration, the computer housing includes the touchpad 1317, the keyboard 1318, and the display 1319 all coupled to the processor 1302. Other configurations of the computing device may include a computer mouse or trackball coupled to the processor (e.g., via a USB input) as are well known, which may also be used in conjunction with the various embodiments.

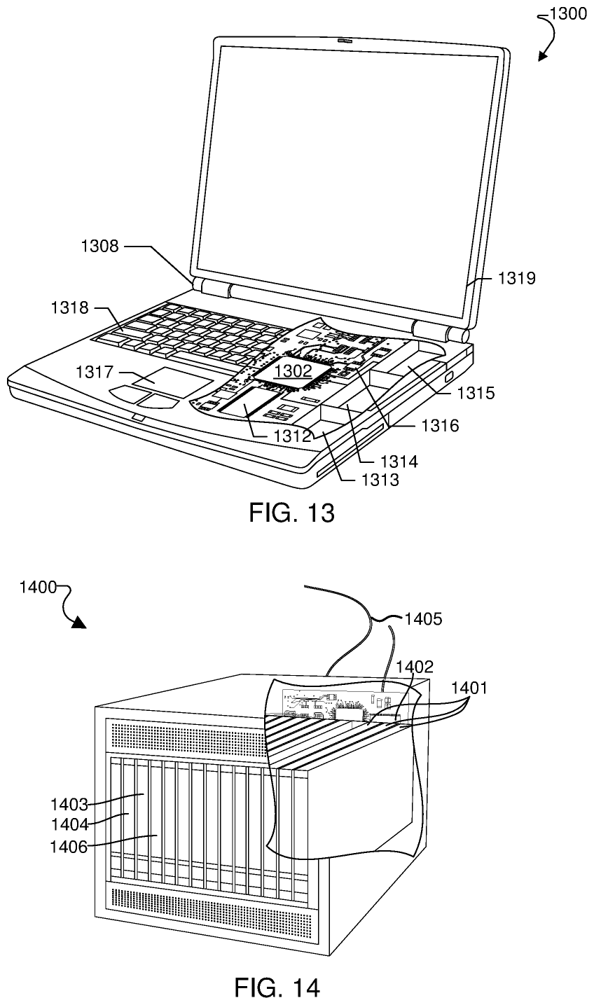

A system in accordance with the various embodiments (including, but not limited to, embodiments described above with reference to FIGS. 1-11) may also be implemented in fixed computing systems, such as any of a variety of commercially available servers. An example server 1400 is illustrated in FIG. 14. Such a server 1400 typically includes one or more multicore processor assemblies 1401 coupled to volatile memory 1402 and a large capacity nonvolatile memory, such as a disk drive 1404. As illustrated in FIG. 14, multicore processor assemblies 1401 may be added to the server 1400 by inserting them into the racks of the assembly. The server 1400 may also include a floppy disc drive, compact disc (CD) or digital versatile disc (DVD) disc drive 1406 coupled to the processor 1401. The server 1400 may also include network access ports 1403 coupled to the multicore processor assemblies 1401 for establishing network interface connections with a network 1405, such as a local area network coupled to other broadcast system computers and servers, the Internet, the public switched telephone network, and/or a cellular data network (e.g., CDMA, TDMA, GSM, PCS, 3G, 4G, LTE, 5G or any other type of cellular data network).

Implementation examples are described in the following paragraphs. While some of the following implementation examples are described in terms of example systems, devices, or methods, further example implementations may include the example systems or devices discussed in the following paragraphs implemented as a non-transitory processor-readable storage medium having stored thereon processor-executable instructions configured to cause a processor of a computing device to perform the operations of the example systems, devices, or methods.

Example 1. A method performed by a bandwidth compressed data mover system of a computing device for moving bandwidth compressed data, including: identifying valid bandwidth compressed data of bandwidth compressed data stored in a memory based on a configuration of a bandwidth compression technique used to generate the bandwidth compressed data, in which the bandwidth compressed data includes valid bandwidth compressed data and invalid bandwidth compressed data; loading the valid bandwidth compressed data from the memory; and writing the valid bandwidth compressed data to an output device.

Example 2. The method of example 1, in which writing the valid bandwidth compressed data to the output device includes copying the valid bandwidth compressed data loaded from the memory to the output device.

Example 3. The method of either of examples 1 or 2, further including serializing the valid bandwidth compressed data loaded from the memory to produce serialized valid bandwidth compressed data, in which writing the valid bandwidth compressed data to the output device includes writing the serialized valid bandwidth compressed data to the output device.

Example 4. The method of example 3, further including compressing the serialized valid bandwidth compressed data to produce compressed serialized valid bandwidth compressed data, in which writing the serialized valid bandwidth compressed data to the output device includes writing the compressed serialized valid bandwidth compressed data to the output device.

Example 5. The method of example 3, in which writing the serialized valid bandwidth compressed data to the output device includes: transmitting the serialized valid bandwidth compressed data to a decoder; decoding the serialized valid bandwidth compressed data in the decoder to produce the valid bandwidth compressed data; and writing the valid bandwidth compressed data decoded to the output device.

Example 6. The method of any of examples 1-5, in which: identifying the valid bandwidth compressed data of the bandwidth compressed data stored in the memory based on the configuration of the bandwidth compression technique used to generate the bandwidth compressed data includes identifying an address in the memory for the valid bandwidth compressed data and a length of the valid bandwidth compressed data from metadata associated with the bandwidth compressed data; and loading the valid bandwidth compressed data from the memory includes loading the valid bandwidth compressed data from the memory based on the address in the memory for the valid bandwidth compressed data and the length of the valid bandwidth compressed data.

Example 7. The method of any of examples 1-6, further including: identifying an address in the memory for the valid bandwidth compressed data using a memory address speculation technique; calculating a length of the valid bandwidth compressed data; and generating metadata to associate with the valid bandwidth compressed data that identifies the address in the memory for the valid bandwidth compressed data and the length of the valid bandwidth compressed data, in which: identifying the valid bandwidth compressed data of the bandwidth compressed data stored in the memory based on the configuration of the bandwidth compression technique used to generate the bandwidth compressed data includes identifying the address in the memory for the valid bandwidth compressed data and the length of the valid bandwidth compressed data from the metadata associated with the valid bandwidth compressed data; and loading the valid bandwidth compressed data from the memory includes loading the valid bandwidth compressed data from the memory based on the address in the memory for the valid bandwidth compressed data and the length of the valid bandwidth compressed data.

Example 8. The method of example 7, further including: identifying mis-speculated valid bandwidth compressed data associated with the address in the memory for the valid bandwidth compressed data; storing the mis-speculated valid bandwidth compressed data in a speculation memory; identifying valid bandwidth compressed data from the mis-speculated valid bandwidth compressed data stored in the speculation memory for a request for bandwidth compressed data; and loading the valid bandwidth compressed data from the speculation memory.

Example 9. The method of any of examples 1-8, further including writing metadata associated with the valid bandwidth compressed data to the output device.

Computer program code or “program code” for execution on a programmable processor for carrying out operations of the various embodiments may be written in a high level programming language such as C, C++, C#, Smalltalk, Java, JavaScript, Visual Basic, a Structured Query Language (e.g., Transact-SQL), Perl, or in various other programming languages. Program code or programs stored on a computer readable storage medium as used in this application may refer to machine language code (such as object code) whose format is understandable by a processor.

The foregoing method descriptions and the process flow diagrams are provided merely as illustrative examples and are not intended to require or imply that the operations of the various embodiments must be performed in the order presented. As will be appreciated by one of skill in the art the order of operations in the foregoing embodiments may be performed in any order. Words such as “thereafter,” “then,” “next,” etc. are not intended to limit the order of the operations; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm operations described in connection with the various embodiments may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the claims.

The hardware used to implement the various illustrative logics, logical blocks, modules, and circuits described in connection with the embodiments disclosed herein may be implemented or performed with a general purpose processor, a digital signal processor (DSP), an application-specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more embodiments, the functions described may be implemented in hardware, software, firmware, or any combination thereof. If implemented in software, the functions may be stored as one or more instructions or code on a non-transitory computer-readable medium or a non-transitory processor-readable medium. The operations of a method or algorithm disclosed herein may be embodied in a processor-executable software module that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed embodiments is provided to enable any person skilled in the art to make or use the claims. Various modifications to these embodiments will be readily apparent to those skilled in the art, and the generic principles defined herein may be applied to other embodiments and implementations without departing from the scope of the claims. Thus, the present disclosure is not intended to be limited to the embodiments and implementations described herein, but is to be accorded the widest scope consistent with the following claims and the principles and novel features disclosed herein.

What is claimed is:

1. A method performed by a bandwidth compressed data mover system of a computing device for moving bandwidth compressed data, comprising:
identifying valid bandwidth compressed data of bandwidth compressed data stored in a memory based on a configuration of a bandwidth compression technique used to generate the bandwidth compressed data, wherein the bandwidth compressed data includes valid bandwidth compressed data and invalid bandwidth compressed data;
loading the valid bandwidth compressed data from the memory; and
writing the valid bandwidth compressed data to an output device.

2. The method of claim 1, wherein writing the valid bandwidth compressed data to the output device comprises copying the valid bandwidth compressed data loaded from the memory to the output device.

3. The method of claim 1, further comprising serializing the valid bandwidth compressed data loaded from the memory to produce serialized valid bandwidth compressed data, wherein writing the valid bandwidth compressed data to the output device comprises writing the serialized valid bandwidth compressed data to the output device.

4. The method of claim 3, further comprising compressing the serialized valid bandwidth compressed data to produce compressed serialized valid bandwidth compressed data, wherein writing the serialized valid bandwidth compressed data to the output device comprises writing the compressed serialized valid bandwidth compressed data to the output device.

5. The method of claim 3, wherein writing the serialized valid bandwidth compressed data to the output device comprises:
transmitting the serialized valid bandwidth compressed data to a decoder;
decoding the serialized valid bandwidth compressed data in the decoder to produce the valid bandwidth compressed data; and
writing the valid bandwidth compressed data decoded to the output device.

6. The method of claim 1, wherein:
identifying the valid bandwidth compressed data of the bandwidth compressed data stored in the memory based on the configuration of the bandwidth compression technique used to generate the bandwidth compressed data comprises identifying an address in the memory for the valid bandwidth compressed data and a length of the valid bandwidth compressed data from metadata associated with the bandwidth compressed data; and
loading the valid bandwidth compressed data from the memory comprises loading the valid bandwidth compressed data from the memory based on the address in the memory for the valid bandwidth compressed data and the length of the valid bandwidth compressed data.

7. The method of claim 1, further comprising:
identifying an address in the memory for the valid bandwidth compressed data using a memory address speculation technique;
calculating a length of the valid bandwidth compressed data; and
generating metadata to associate with the valid bandwidth compressed data that identifies the address in the memory for the valid bandwidth compressed data and the length of the valid bandwidth compressed data,
wherein:
identifying the valid bandwidth compressed data of the bandwidth compressed data stored in the memory based on the configuration of the bandwidth compression technique used to generate the bandwidth compressed data comprises identifying the address in the memory for the valid bandwidth compressed data and the length of the valid bandwidth compressed data from the metadata associated with the valid bandwidth compressed data; and
loading the valid bandwidth compressed data from the memory comprises loading the valid bandwidth compressed data from the memory based on the address in the memory for the valid bandwidth compressed data and the length of the valid bandwidth compressed data.

8. The method of claim 7, further comprising:
identifying mis-speculated valid bandwidth compressed data associated with the address in the memory for the valid bandwidth compressed data;
storing the mis-speculated valid bandwidth compressed data in a speculation memory;
identifying valid bandwidth compressed data from the mis-speculated valid bandwidth compressed data stored in the speculation memory for a request for bandwidth compressed data; and
loading the valid bandwidth compressed data from the speculation memory.

9. The method of claim 1, further comprising writing metadata associated with the valid bandwidth compressed data to the output device.

10. A computing device performed by of a for moving bandwidth compressed data, comprising:
a memory; and
a bandwidth compressed data mover system coupled to the memory and configured to:
identify valid bandwidth compressed data of bandwidth compressed data stored in the memory based on a configuration of a bandwidth compression technique used to generate the bandwidth compressed data, wherein the bandwidth compressed data includes valid bandwidth compressed data and invalid bandwidth compressed data;
load the valid bandwidth compressed data from the memory; and
write the valid bandwidth compressed data to an output device.

11. The computing device of claim 10, wherein the bandwidth compressed data mover system is further configured to write the valid bandwidth compressed data to the output device by copying the valid bandwidth compressed data loaded from the memory to the output device.

12. The computing device of claim 10, wherein the bandwidth compressed data mover system is further configured to:
serialize the valid bandwidth compressed data loaded from the memory to produce serialized valid bandwidth compressed data; and
write the valid bandwidth compressed data to the output device by writing the serialized valid bandwidth compressed data to the output device.

13. The computing device of claim 12, wherein the bandwidth compressed data mover system is further configured to:
compressing the serialized valid bandwidth compressed data to produce compressed serialized valid bandwidth compressed data; and
write the serialized valid bandwidth compressed data to the output device by writing the compressed serialized valid bandwidth compressed data to the output device.

14. The computing device of claim 12, wherein the bandwidth compressed data mover system is further configured to write the serialized valid bandwidth compressed data to the output device by:
transmitting the serialized valid bandwidth compressed data to a decoder;
decoding the serialized valid bandwidth compressed data in the decoder to produce the valid bandwidth compressed data; and
writing the valid bandwidth compressed data decoded to the output device.

15. The computing device of claim 10, wherein the bandwidth compressed data mover system is further configured to:
identify the valid bandwidth compressed data of the bandwidth compressed data stored in the memory based on the configuration of the bandwidth compression technique used to generate the bandwidth compressed data by identifying an address in the memory for the valid bandwidth compressed data and a length of the valid bandwidth compressed data from metadata associated with the bandwidth compressed data; and
load the valid bandwidth compressed data from the memory by loading the valid bandwidth compressed data from the memory based on the address in the memory for the valid bandwidth compressed data and the length of the valid bandwidth compressed data.

16. The computing device of claim 10, wherein the bandwidth compressed data mover system is further configured to:
identify an address in the memory for the valid bandwidth compressed data using a memory address speculation technique;
calculate a length of the valid bandwidth compressed data;
generate metadata to associate with the valid bandwidth compressed data that identifies the address in the memory for the valid bandwidth compressed data and the length of the valid bandwidth compressed data;
identify the valid bandwidth compressed data of the bandwidth compressed data stored in the memory based on the configuration of the bandwidth compression technique used to generate the bandwidth compressed data by identifying the address in the memory for the valid bandwidth compressed data and the length of the valid bandwidth compressed data from the metadata associated with the valid bandwidth compressed data; and
load the valid bandwidth compressed data from the memory by loading the valid bandwidth compressed data from the memory based on the address in the memory for the valid bandwidth compressed data and the length of the valid bandwidth compressed data.

17. The computing device of claim 16, wherein the bandwidth compressed data mover system is further configured to:
identify mis-speculated valid bandwidth compressed data associated with the address in the memory for the valid bandwidth compressed data;
store the mis-speculated valid bandwidth compressed data in a speculation memory;
identify valid bandwidth compressed data from the mis-speculated valid bandwidth compressed data stored in the speculation memory for a request for bandwidth compressed data; and
load the valid bandwidth compressed data from the speculation memory.

18. The computing device of claim 10, wherein the bandwidth compressed data mover system is further configured to write metadata associated with the valid bandwidth compressed data to the output device.

19. A non-transitory processor-readable medium having stored thereon processor executable instructions configured to cause a bandwidth compressed data mover system of a computing device to perform operations comprising:
identifying valid bandwidth compressed data of bandwidth compressed data stored in a memory based on a configuration of a bandwidth compression technique used to generate the bandwidth compressed data, wherein the bandwidth compressed data includes valid bandwidth compressed data and invalid bandwidth compressed data;
loading the valid bandwidth compressed data from the memory; and
writing the valid bandwidth compressed data to an output device.

20. The non-transitory processor-readable medium of claim 19, wherein the stored processor executable instructions are configured to cause the bandwidth compressed data mover system of the computing device to perform operations further comprising serializing the valid bandwidth compressed data loaded from the memory to produce serialized valid bandwidth compressed data, wherein writing the valid bandwidth compressed data to the output device comprises writing the serialized valid bandwidth compressed data to the output device.
